(19) United States
(12) Patent Application Publication
(10) Pub. No.: US 2026/0070778 A1
(43) Pub. Date: Mar. 12, 2026

(54) MICROELECTROMECHANICAL SYSTEM DEVICE WITH FILLED VIA

(71) Applicant: TEXAS INSTRUMENTS INCORPORATED, Dallas, TX (US)

(72) Inventors: Sean C. O'BRIEN, Dallas, TX (US); John HAMLIN, Dallas, TX (US); Song ZHENG, Fairview, TX (US); Christopher BEARD, Allen, TX (US); Andrew CHEN, Plano, TX (US)

(21) Appl. No.: 18/827,161

(22) Filed: Sep. 6, 2024

(51) Int. Cl. B81B 7/00; B81C 1/00

(52) U.S. Cl. CPC B81B 7/0006; B81C 1/00095; B81B 2201/042; B81B 2203/0163; B81B 2203/04; B81B 2207/07; B81B 2207/096; B81C 2201/0105; B81C 2201/013; B81C 2201/0176

(57) ABSTRACT

A microelectromechanical system (MEMS) device includes: a mechanical layer; a second layer; and a via coupled between the mechanical layer and the second layer. The via comprising a metal layer having a bottom and sides, and oxide on the bottom of the metal layer between the sides of the metal layer.

### BACKGROUND

Some microelectromechanical system (MEMS) devices rely on a hinge, where hinge durability and consistent movement are desirable attributes. In a phase-light modulator (PLM) or spatial light modulator (SLM) with an array of MEMS devices, non-uniformity of hinge metal dimensions for different MEMS devices of the array may result in undesirable durability and movement variance.

### SUMMARY

In an example, a microelectromechanical system (MEMS) device includes: a mechanical layer; a second layer; and a via coupled between the mechanical layer and the second layer. The via comprises a metal layer having a bottom and sides, and oxide on the bottom of the metal layer between the sides of the metal layer.

In another example, a method of manufacturing a MEMS device, the method including: forming an opening in a sacrificial layer; depositing metal in the opening to form a via; filling the via with spin-on oxide filler; and etching the spin-on oxide filler.

In yet another example, a MEMS device includes: a mirror layer; an electrode layer including an electrode; a hinge layer; a first via coupling the hinge and the mirror layer; and a second via coupling the hinge layer and the electrode, the second via comprising an oxide filler.

### BRIEF DESCRIPTION OF THE DRAWINGS

FIG. 1A is an exploded view of a microelectromechanical system (MEMS) device in accordance with various examples.

FIG. 1B is a perspective view of the MEMS device of FIG. 1A.

FIG. 2A is an exploded view of a MEMS device in accordance with various examples.

FIG. 2B is a perspective view of the MEMS device of FIG. 2A.

FIG. 2C is a first cross-sectional view of the MEMS device of FIG. 2A.

FIG. 2D is a second cross-sectional view of the MEMS device of FIG. 2A.

FIG. 2E is a see through top view of the MEMS device of FIG. 2A.

FIGS. 3 to 6 are perspective views of other MEMS devices in accordance with various examples.

FIGS. 7A and 7B are cross-sectional views showing filler application and etching results in accordance with various examples.

FIG. 8 is a graph showing via and filler dimensions in accordance with various examples.

FIGS. 9A and 9B are cross-sectional views showing some MEMS device layers during fabrication in accordance with various examples.

FIG. 10 is a cross-sectional view showing subsequent fabrication results for a MEMS device relative to FIGS. 9A and 9B in accordance with various examples.

FIG. 11 is a flowchart showing a MEMS device fabrication method in accordance with various examples.

FIG. 12 is a flowchart showing a MEMS device hinge fabrication method in accordance with various examples.

FIGS. 13A to 13M are cross-sectional views of MEMS device fabrication steps in accordance with various examples.

### DETAILED DESCRIPTION

The same reference numbers or other reference designators are used in the drawings to designate the same or similar features. Such features may be the same or similar either by function and/or structure.

Described herein are microelectromechanical system (MEMS) devices with layers and with one or more filled vias. Example layers include an electrode layer, a mechanical layer, and a moving element(s) layer. In such examples, one or more filled vias may couple the mechanical layer to the moving element(s) layer. Additionally, or alternatively, one or more filled vias may couple the mechanical layer to the electrode layer.

In some examples, a filled via is based on application of a spin-on filler (e.g., oxide). In some examples, a filled via is used to achieve a target thickness uniformity for the via or related metal layers. In one example, at least some filler of a filled via is temporary. For example, the filled via may be used to achieve a target thickness uniformity for the via or related metal layers and then some or all of the filler is removed by etching or other fabrication processes.

In some examples, a target amount of filler remains in a filled via of a completed MEMS device. The target amount of filler may vary and may be based on target characteristics of the related via. Examples of target characteristics include flexibility, rigidity, durability, and/or mechanical strength. As the amount of filler remaining in a filled via increases, via flexibility decreases, while via rigidity, via durability, and/or via mechanical strength increases. As the amount of filler remaining in a filled via decreases, via flexibility increases, while via rigidity, via durability, and/or via mechanical strength decreases. In some examples, a MEMS device may include one or more unfilled via and one or more filled vias. Unfilled vias of a MEMS device may be used to expedite or reduce cost of fabrication where uniformity and planarization (flatness) of the vias or related MEMS device layers have low priority. Meanwhile, each filled via is used to achieve target characteristics such as uniform planarization (flatness) of the filled via, rigidity, or mechanical strength. In different examples, different vias of a MEMS device may vary with regard to dimensions and being a filled via or an unfilled via. For different filled vias, the amount of filler remaining in each filled via of the completed MEMS device may vary. In some cases, all filler of a filled via is eventually removed.

In some examples, each MEMS device is a pixel of a display. In different examples, such MEMS devices are organized into an array of pixels for a spatial light modulator (SLM), such as a digital micromirror device (DMD), or a phase light modulator (PLM). While the figures are directed to a single MEMS device or pixel and related filled via options, the related benefits (e.g., improved planarization, rigidity, durability, etc.) are applicable to a single pixel as well as devices with an array of pixels (e.g., a DMD, PLM, SLM, etc.). During operations, each DMD, SLM, or PLM receives data from a controller to control on/off states of the pixels.

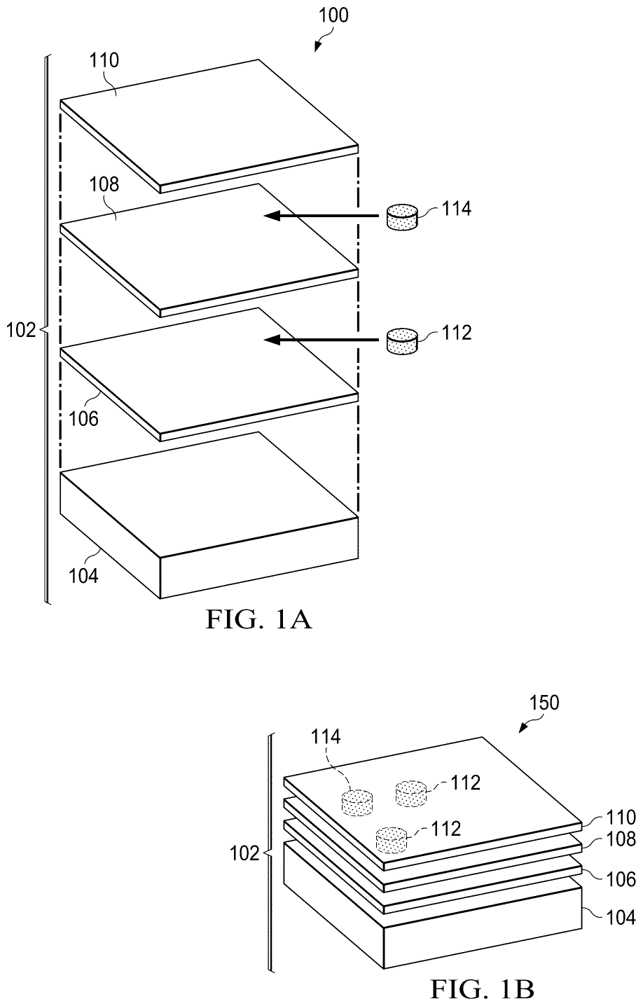

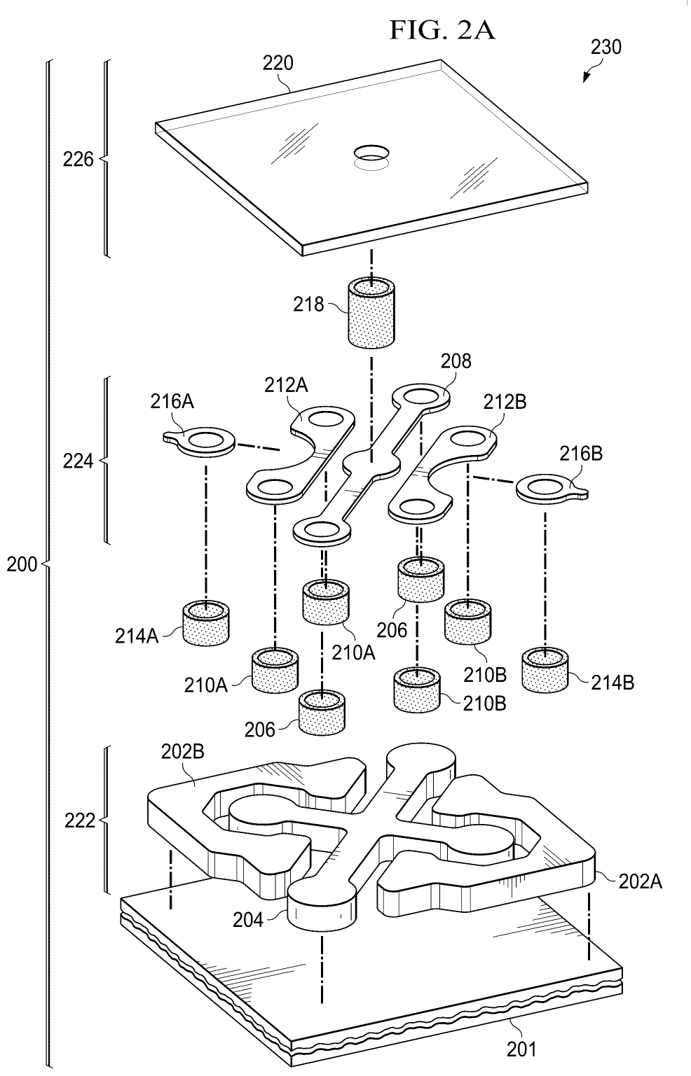

FIG. 1A is an exploded view 100 of a microelectromechanical system (MEMS) device 102 in accordance with various examples. The MEMS device 102 includes a base 104, an electrode layer 106, filled via(s) 112, a mechanical layer 108, filled via(s) 114, and a moving element(s) layer 110. The base 104 includes memory cells (not shown) to control different states of the MEMS device 102 responsive to received data. In some examples, the electrode layer 106 includes first and second electrodes coupled to the base 104. In some examples, filled via(s) 112 may include filled electrode vias, filled spring tip vias, and/or filled hinge vias. In some examples, the mechanical layer 108 includes one or more hinges, raised electrodes, spring tips, and/or other components. In some examples, filled via(s) 114 may include a filled mirror via. In some examples, the moving element(s) layer 110 includes a mirror.

In some examples, the filled via(s) 112 couple the mechanical layer 108 to the electrode layer 106. Additionally, or alternatively, the filled via(s) 114 may couple the mechanical layer 108 to the moving element(s) layer 110. In some examples, a MEMS device may include a combination of filled vias (e.g., the filled via(s) 112 and/or the filled via(s) 114) and unfilled vias.

In some examples, each filled via(s) 112 is a hinge layer via (HVIA) and each filled via(s) 114 is a mirror via (MVIA). In one example, HVIAs and MVIAs are not filled. In another example, HVIAs are filled and MVIAs are not filled. In another example, HVIAs are filled and MVIAs are filled. In another example, HVIAs are not filled and MVIAs are filled.

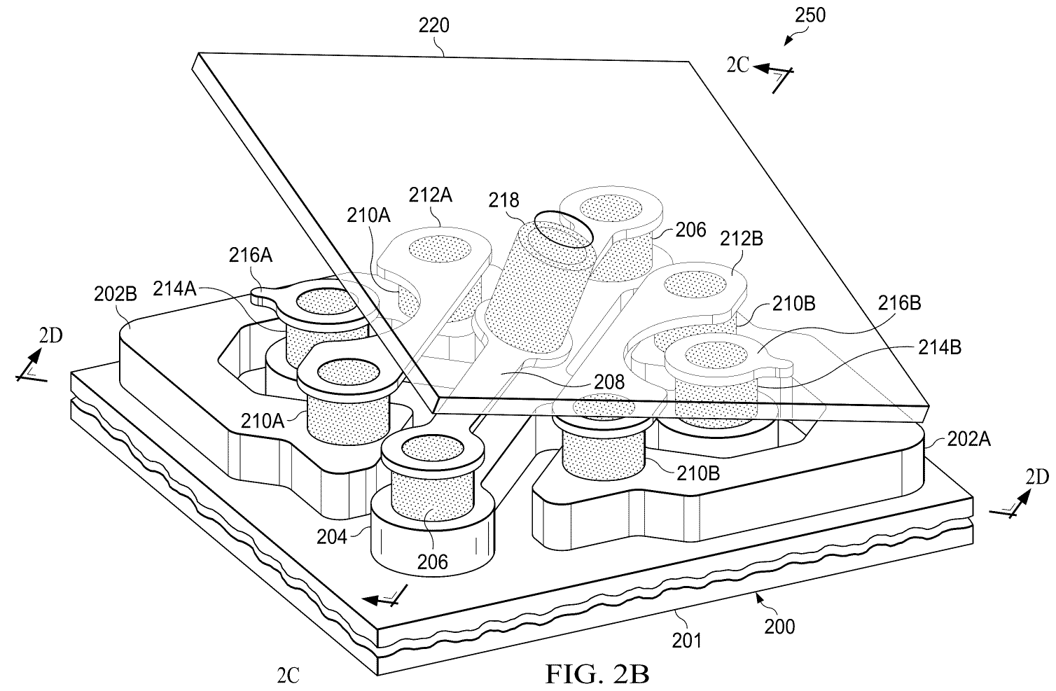

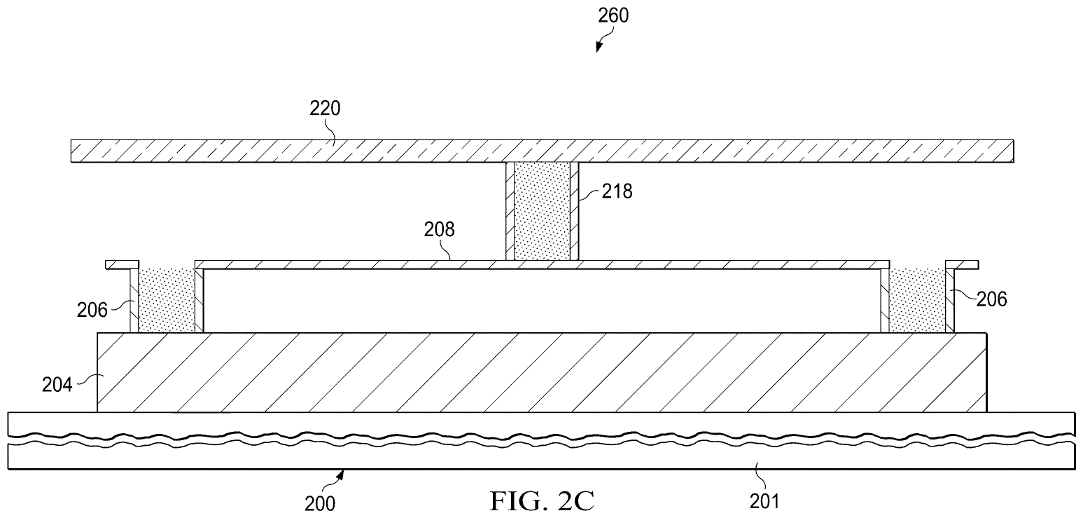

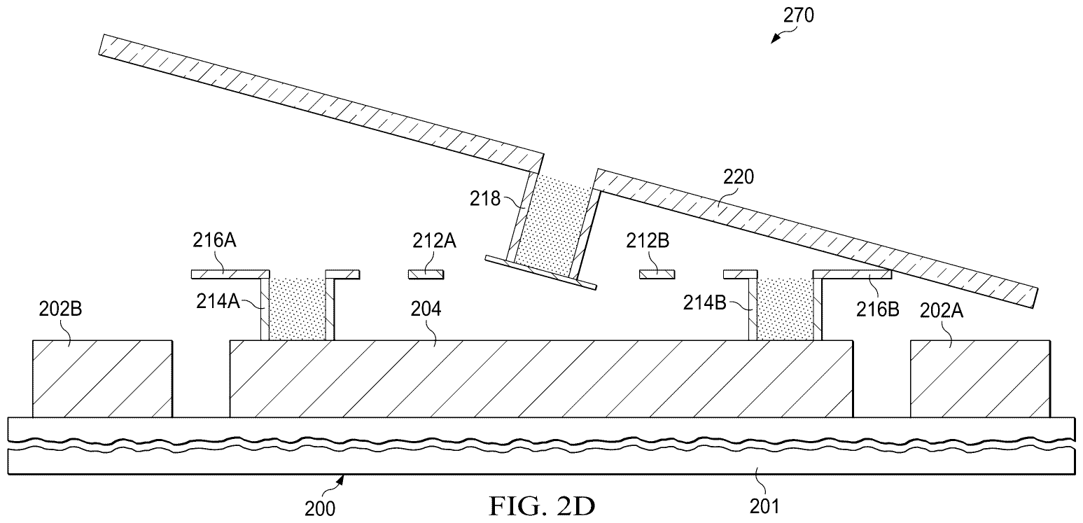

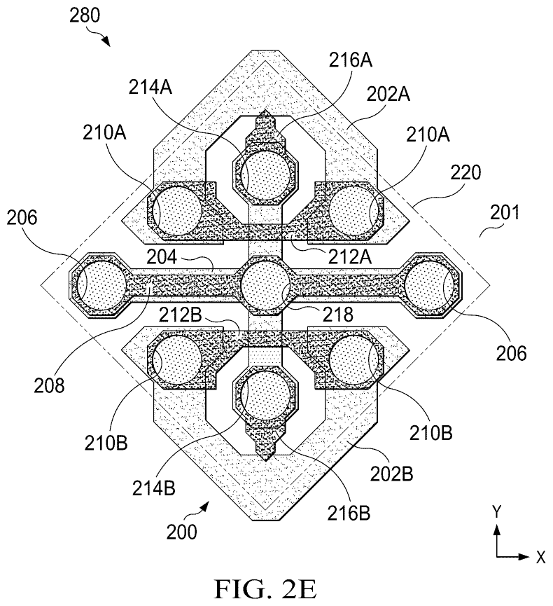

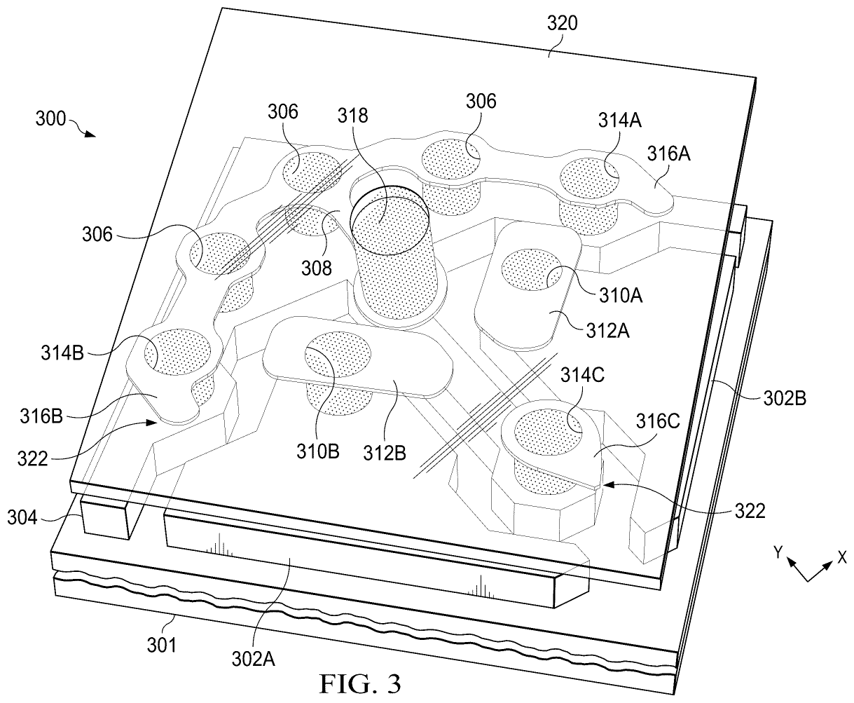

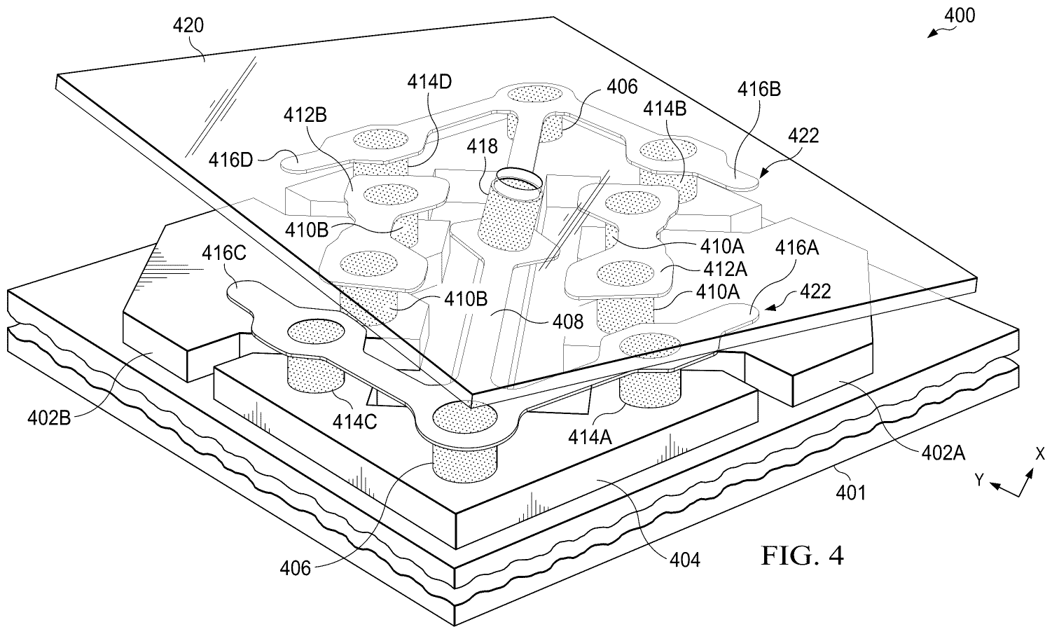

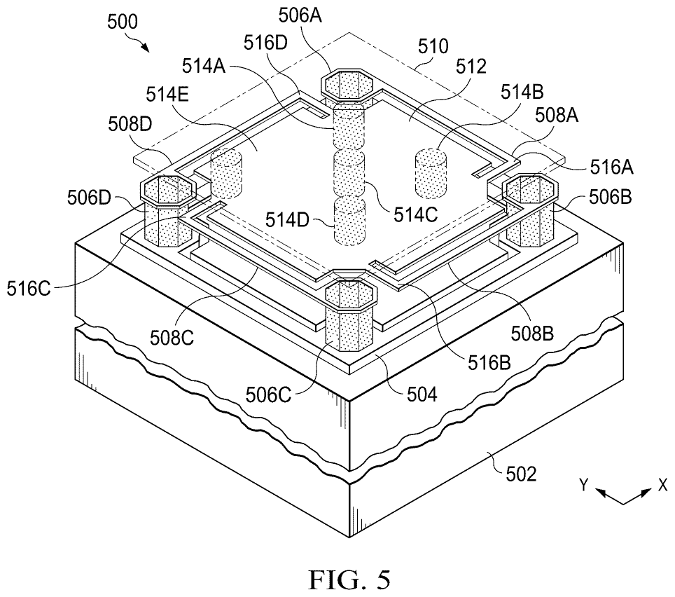

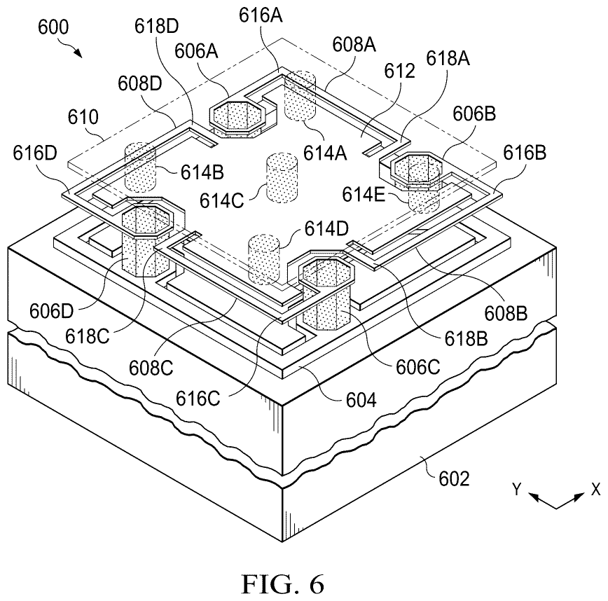

In some examples, the MEMS device 102 may be part of a single spring tip pixel as in FIGS. 2A to 2E. In other examples, the MEMS device 102 may be part of a tilt and roll pixel (TRP) element as in FIG. 3. In other examples, the MEMS device 102 may be part of a dual spring tip pixel as in FIG. 4. In other examples, the MEMS device 102 may be part of a PLM pixel as in FIG. 5 or FIG. 6

FIG. 1B is a perspective view 150 of the MEMS device 102 of FIG. 1A in accordance with various examples. In the example of FIG. 1B, the MEMS device 102 includes the base 104, the electrode layer 106, the mechanical layer 108, and the moving element(s) layer 110 stacked together. In the example of FIG. 1B, filled via(s) 112 couple the electrode layer 106 and the mechanical layer 108. Also, filled via(s) 114 couple the mechanical layer 108 and the moving element(s) layer 110.

In an example SLM, the moving element(s) layer 110 of the MEMS device 102 tilts between two or more positions based on: received data; and operations of the base 104 and the mechanical layer 108 responsive to the received data. In an example PLM, the moving element(s) layer 110 of the MEMS device moves up and down between two or more positions based on: received data; and operations of the base 104 and the mechanical layer 108 responsive to the received data. In different examples, the number of total vias and the number of filled vias between the mechanical layer 108 and the electrode layer 106 may vary. Similarly, in different examples, the number of total vias and the number of filled vias between the mechanical layer 108 and the moving element(s) layer 110 may vary. The dimensions of each filled via may vary and may be selected to facilitate layout, spacing, and/or miniaturization of a particular MEMS device or related product. Without limitation, the MEMS device 102 may be used to form a pixel of a SLM or a PLM of a display system. Example pixel sizes that may benefit from the MEMS device 102 and related filled vias may range from 16 μm pixels down to 2.7 μm pixels or smaller.

FIGS. 2A to 2E are different views of an example MEMS device 200. FIG. 2A is an exploded view 230 of the MEMS device 200. FIG. 2B is a perspective view 250 of the MEMS device 200. FIG. 2C is a first cross-sectional view 260 of the MEMS device 200. FIG. 2D is a second cross-sectional view 270 of the MEMS device 200. FIG. 2E is a see through top view 280 of the MEMS device 200. In the example of FIG. 2A, the MEMS device 200 is an example of a single spring tip pixel. As shown, the MEMS device 200 includes a base 201, an electrode layer 222, hinge vias 206, first electrode vias 210A, second electrode vias 210B (collectively electrode vias 210), a first spring tip via 214A, a second spring tip via 214B, a mechanical layer 224, a mirror via 218, and a mirror layer 226 with mirror 220. In the example of FIG. 2A, the base 201 is split to represent its thickness may vary. The base 201 may include transistor circuitry to control different states of the MEMS device 200 responsive to received data. In some examples, the base 201 includes memory cells under the pixels. The electrode layer 222 is an example of the electrode layer 106 in FIGS. 1A and 1B. In some examples, the hinge vias 206, the first electrode vias 210A, the second electrode vias 210B, the first spring tip via 214A, and the second spring tip via 214B are examples of the filled via(s) 112 in FIGS. 1A and 1B. The mechanical layer 224 is an example of the mechanical layer 108 in FIGS. 1A and 1B. In some examples, the mirror via 218 is an example of the filled via(s) 114 in FIGS. 1A and 1B. The mirror layer 226 is an example of the moving element(s) layer 110 in FIGS. 1A and 1B.

In the example of FIG. 2A, the electrode layer 222 includes a first address electrode 202A, a second address electrode 202B, and a bias electrode 204 spaced from the first and second address electrodes 202A and 202B. In some examples, there are two of the hinge vias 206, two of the first electrode vias 210A, two of the second electrode vias 210B, one first spring tip via 214A, one second spring tip via 214B, and one mirror via 218. In other examples, the number of hinge vias 206, the number of first electrode vias 210A, the number of second electrode vias 210B, the number of first spring tip vias 214A, the number of second spring tip vias 214B, and/or the number of mirror vias 218 may vary. In the example of FIG. 2A, each of the hinge vias 206, each of the first electrode vias 210A, each of the second electrode vias 210B, the first spring tip via 214A, the second spring tip via 214B, and the mirror via 218 is a filled via. In other examples, one or more of the hinge vias 206, the first electrode vias 210A, the second electrode vias 210B, the first spring tip via 214A, the second spring tip via 214B, and the mirror via 218 may be an unfilled via while others of the hinge vias 206, the first electrode vias 210A, the second electrode vias 210B, the first spring tip via 214A, the second spring tip via 214B, and the mirror via 218 are filled vias. In some examples, the hinge vias 206 are filled vias, which leads to improved hinge width uniformity and flatter mirrors.

In the example of FIG. 2A, the mechanical layer 224 includes a torsion hinge 208, a first raised electrode 212A, a second raised electrode 212B, a first spring tip 216A, and a second spring tip 216B. In other examples, the mechanical layer 224 may include multiple torsion hinges 208, multiple first raised electrodes 212A, multiple second raised electrodes 212B, multiple first spring tips 216A, and/or multiple second spring tips 216B. In the example of FIG. 2A, the mirror layer 226 includes a mirror 220. In other examples, the mirror layer 226 may include multiple mirrors 220.

FIG. 2B is a perspective view 250 of the MEMS device 200 of FIG. 2A. In the example of FIG. 2B, the base 201, the components of the electrode layer 222, the components of the mechanical layer 224, the hinge vias 206, the first electrode vias 210A, the second electrode vias 210B, the first spring tip via 214A, the second spring tip via 214B, the mirror via 218, and components of the mirror layer 226 are represented. In the example of FIG. 2B, the base 201 is split to represent its thickness may vary. As shown, the position of the mirror 220 is tilted. In an example SLM, the position of the mirror 220 switches between different tilted positions responsive to: received data; control voltages applied to the first address electrode 202A, the second address electrode 202B, and the bias electrode 204 responsive to received data; and movement of the torsion hinge 208 and mirror 220 responsive to application of the control voltages.

In the example of FIG. 2B, the mirror 220 is in a first position, in which the mirror 220 contacts the second spring tip 216B responsive to control voltages applied to the first address electrode 202A, the second address electrode 202B, and the bias electrode 204. To change the position of the mirror 220 to another position (e.g., with the mirror 220 contacting the first spring tip 216A), updated control voltages are applied to the first address electrode 202A, the second address electrode 202B, and/or the bias electrode 204.

In different examples, the number of total vias and the number of filled vias between the mechanical layer 224 and the electrode layer 222 may vary. Similarly, in different examples, the number of total vias and the number of filled vias between the mechanical layer 224 and the mirror layer 226 may vary. The dimensions of each via may vary and may be selected to facilitate layout, spacing, and/or miniaturization of a particular MEMS device or related product. Without limitation, the MEMS device 200 may be used to form a pixel of a SLM of a display system. Example pixel sizes that may benefit from the MEMS device 200 and related filled via(s) include 9 μm pixels, 6 μm pixels, 5.4 μm pixels, 5.0 μm pixels, 4.5 μm pixels, 4.0 μm pixels, 3.6 μm pixels, 2.7 μm pixels, or other pixel dimensions. For the example pixel sizes, pixel pitch (side-to-side size) is used, and square pixels are assumed.

FIG. 2C is a first cross-sectional view 260 of the MEMS device 200 of FIG. 2A. In the first cross-sectional view 260, part of the mirror 220, part of the mirror via 218, part of the hinge vias 206, part of the torsion hinge 208, and part of the base 201 are visible. In the example of FIG. 2C, the base 201 is split to represent its thickness may vary.

FIG. 2D is a second cross-sectional view 270 of the MEMS device 200 of FIG. 2A. In the second cross-sectional view 270, part of the mirror 220, part of the mirror via 218, part of the first spring tip via 214A, part of the first spring tip 216A, part of the first raised electrode 212A, part of the second spring tip via 214B, part of the second spring tip 216B, part of one of the second electrode vias 210B, part of the first raised electrode 212A, part of the second raised electrode 212B, part of the first address electrode 202A, part of the second address electrode 202B, part of the bias electrode 204, and part of the base 201 are visible. In the example of FIG. 2D, the base 201 is split to represent its thickness may vary.

FIG. 2E is a see through top view 280 of the MEMS device 200 of FIG. 2A. In the see through top view 280, the relative position, size, and spacing of the base 201, the first address electrode 202A, the second address electrode 202B, the bias electrode 204, the hinge vias 206, the torsion hinge 208, the first electrode vias 210A, the first raised electrode 212A, the first spring tip via 214A, the first spring tip 216A, the second electrode vias 210B, the second raised electrode 212B, the second spring tip via 214B, the second spring tip 216B, and the mirror via 218 are shown. In the example of FIG. 2E, each of the hinge vias 206, each of the first electrode vias 210A, each of the second electrode vias 210B, the first spring tip via 214A, the second spring tip via 214B, and the mirror via 218 are filled vias. In other examples, one or more of the hinge vias 206, the first electrode vias 210A, the second electrode vias 210B, the first spring tip via 214A, the second spring tip via 214B, and the mirror via 218 may be an unfilled via while others of the hinge vias 206, the first electrode vias 210A, the second electrode vias 210B, the first spring tip via 214A, the second spring tip via 214B, and the mirror via 218 are filled vias. In one example, only the mirror via 218 is a filled via, while the hinge vias 206, the first electrode vias 210A, the second electrode vias 210B, the first spring tip via 214A, and the second spring tip via 214B are unfilled vias. In another example, only the first spring tip via 214A and the second spring tip via 214B are filled vias, while the hinge vias 206, the first electrode vias 210A, the second electrode vias 210B, and the mirror via 218 are unfilled vias. In another example, mirror via 218, the first spring tip via 214A, and the second spring tip via 214B are filled vias, while the hinge vias 206, the first electrode vias 210A, and the second electrode vias 210B are unfilled vias. Other combinations of filled vias and unfilled vias are possible as well.

Table 1 shows different combinations of filled vias types that are possible. In Table 1, A refers to filled hinge vias (e.g., the hinge vias 206 are filled), B refers to filled first electrode vias (e.g., the first electrode vias 210 are filled), C refers to filled second electrode vias (e.g., the second electrode vias 210B are filled), D refers to a filled first spring tip via (e.g., the first spring tip via 214A is filled), E refers to a filled second spring tip via (e.g., the second spring tip via 214B is filled, and F refers to a filled mirror via (e.g., the mirror via 218 is filled).

TABLE 1

| 1 via type | 2 via types | 3 via types | 4 via types | 5 via types | 6 via types |
|---|---|---|---|---|---|
| filled | filled | filled | filled | filled | filled |
| A | AB | ABC | ABCD | ABCDE | ABCDEF |
| B | AC | ABD | ABCE | ABCDF | |
| C | AD | ABE | ABCF | ABCEF | |
| D | AE | ABF | ABDE | ACDEF | |
| E | AF | ACD | ABDF | ACDEF | |
| F | BC | ACE | ABEF | BADEF | |
| | BD | ACF | ACDE | BCDEF | |
| | BE | ADE | ACDF | | |
| | BF | ADF | ACEF | | |
| | CD | AEF | ADEF | | |
| | CE | BCD | BCDE | | |
| | CF | BCE | BCDF | | |
| | DE | BCF | BCEF | | |
| | DF | BDE | BDEF | | |
| | EF | BDF | CDEF | | |
| | | BEF | | | |
| | | CDE | | | |
| | | CDF | | | |
| | | CEF | | | |
| | | DEF | | | |

As represented in Table 1, there are up to 63 ways to combine the 6 types of filled vias represented by the letters A, B, C, D, E, F. In different examples, each of the combinations represented in Table 1 may be used for a MEMS device such as the MEMS device 200 of FIGS. 2A to 2E. In some examples, used filled hinge vias (e.g., the hinge vias 206 are filled) provide the advantages of improved hinge width uniformity and/or flatter mirrors and may be prioritized over other filled via options. Other types of filled vias, including filled first electrode vias (e.g., the first electrode vias 210 are filled), filled second electrode vias (e.g., the second electrode vias 210B are filled), a filled first spring tip via (e.g., the first spring tip via 214A is filled), a filled second spring tip via (e.g., the second spring tip via 214B is filled, and a filled mirror via (e.g., the mirror via 218 is filled), may provide improved reliability over time in ambient settings that vary with regard to temperature range, ultraviolet light exposure, or other ambient settings that may otherwise reduce reliability.

In the example of FIG. 2E, the first and second address electrodes 202A and 202B extend beyond the outline of the mirror 220. In such examples, the first and second address electrodes 202A and 202B may extend partially (e.g., halfway or less) into the gap between mirrors. In other examples, the first and second address electrodes 202A and 202B do not extend beyond the outline of the mirror 220.

In the example of FIGS. 2A to 2E, unfilled vias of a MEMS device may be used to expedite or reduce cost of fabrication where uniformity and planarization (flatness) of the vias or related MEMS device layers have low priority. Meanwhile, each filled via is used to achieve target characteristics such as uniform planarization (flatness) of the filled via, rigidity, or mechanical strength.

FIGS. 3 to 6 are perspective views of other MEMS devices 300, 400, 500, and 600 and in accordance with various examples. In FIG. 3, the MEMS device 300 is an example of a TRP pixel (sometimes referred to as a “cantilever” pixel). In the example of FIG. 3, the MEMS device 300 includes a base 301, a first address electrode 302A, a second address electrode 302B, a bias electrode 304, spring tip vias 314A to 314C, a first electrode via 310A, a second electrode via 310B, hinge vias 306, a cantilever hinge 308, spring tips 316A to 316C, a first raised electrode 312A, a second raised electrode 312B, a mirror via 318, and a mirror 320. The base 301 is an example of the base 104 in FIG. 1. The first address electrode 302A, the second address electrode 302B, and the bias electrode 304 are example components of the electrode layer 106 in FIG. 1. The spring tip vias 314A to 314C, the first electrode via 310A, the second electrode via 310B, and the hinge vias 306 are examples of the filled via(s) 112 in FIG. 1. The cantilever hinge 308, the spring tips 316A to 316C, the first raised electrode 312A, and the second raised electrode 312B are example components of the mechanical layer 108 in FIG. 1. The mirror via 318 is an example of the filled via(s) 114 in FIG. 1. The mirror 320 is an example component of the moveable element(s) layer 110 in FIG. 1.

In the example of FIG. 3, various filled vias are represented including spring tip vias 314A to 314C, the first electrode via 310A, the second electrode via 310B, hinge vias 306, and a mirror via 318. With the filled vias of FIG. 3, target characteristics for planarization (flatness) of the filled via, rigidity, or mechanical strength is achieved. In some examples, filled hinge vias (e.g., when the hinge vias 306 are filled) provide the advantages of improved hinge width uniformity and/or flatter mirrors. Other types of filled vias, including filled first electrode vias (e.g., when the first electrode via 310A is filled), filled second electrode vias (e.g., when the second electrode via 310B is filled), filled spring tip vias (e.g., when the spring tip vias 314A to 314C are filled), and a filled mirror via (e.g., when the mirror via 318 is filled), may provide improved reliability over time in ambient settings that vary with regard to temperature range, ultraviolet light exposure, or other ambient settings that may otherwise reduce reliability.

In different examples, some of the spring tip vias 314A to 314C, the first electrode via 310A, the second electrode via 310B, the hinge vias 306, and the mirror via 318 may be unfilled vias while other vias are filled vias. In different examples, the number of filled vias may vary to support different MEMS device characteristics (e.g., via uniformity or flatness, via rigidity or flexibility, via durability/mechanical strength, etc.).

Table 2 shows different combinations of filled vias types that are possible for the example of FIG. 3. In Table 2, G refers to filled hinge vias (e.g., the hinge vias 306 are filled), H refers to a filled first electrode via (e.g., the first electrode via 310A is filled), I refers to a filled second electrode via (e.g., the second electrode via 310B is filled), J refers to filled spring tip vias (e.g., the spring tip via 314A to 314C are filled), and K refers to a filled mirror via (e.g., the mirror via 318 is filled).

TABLE 2

| 1 via type | 2 via types | 3 via types | 4 via types | 5 via types |
|---|---|---|---|---|
| filled | filled | filled | filled | filled |
| G | GH | GHI | GHIJ | GHIJK |
| H | GI | GHJ | GHIK | |
| I | GJ | GHK | GHJK | |
| J | GK | GIJ | GIJK | |
| K | HI | GIK | HIJK | |
| | HJ | GJK | | |
| | HK | HIJ | | |
| | IJ | HIK | | |
| | IK | HJK | | |
| | JK | IJK | | |

As represented in Table 2, there are up to 31 ways to combine the 5 types of filled vias represented by the letters G, H, I, J, and K. In different examples, each of the combinations represented in Table 2 may be used for a MEMS device such as the MEMS device 300 of FIG. 3. In some examples, filled hinge vias (e.g., the hinge vias 306 are filled) provide the advantages of improved hinge width uniformity and/or flatter mirrors and may be prioritized over other filled via options. Other types of filled vias, including a filled first electrode vias (e.g., the first electrode via 310A is filled), a filled second electrode via (e.g., the second electrode via 310B is filled), filled spring tip via (e.g., the spring tip via 314A to 314C are filled), and a filled mirror via (e.g., the mirror via 318 is filled), may provide improved reliability over time in ambient settings that vary with regard to temperature range, ultraviolet light exposure, or other ambient settings that may otherwise reduce reliability.

As shown, the position of the mirror 320 is tilted towards the spring tips 316B and 316C, which may be an on position for the mirror 320. In an example SLM, the position of the mirror 320 switches between different tilted positions (e.g., an on position in which the mirror 320 contacts spring tips 316B and 316C, and an off position in which the mirror 320 contacts the spring tips 316A and 316C) responsive to: received data; control voltages applied to the first address electrode 302A, the second address electrode 302B, and the bias electrode 304 responsive to received data; and movement of the cantilever hinge 308 and mirror 320 responsive to application of the control voltages.

In the example of FIG. 3, the mirror 320 is in a first position, in which the mirror 320 contacts the spring tips 316B and 316C at contact points 322 responsive to control voltages applied to the first address electrode 302A, the second address electrode 302B, and the bias electrode 304. To change the position of the mirror 320 to another position (e.g., the mirror 320 may contact the spring tips 316A and 316B), updated control voltages are applied to the first address electrode 302A, the second address electrode 302B, and/or the bias electrode 304.

In different examples, the number of total vias and the number of filled vias between mechanical layer components and electrode layer components may vary. Similarly, in different examples, the number of total vias and the number of filled vias between mechanical layer components and mirror layer components may vary. The dimensions of each filled via may vary and may be selected to facilitate layout, spacing, and/or miniaturization of a particular MEMS device or related product. Without limitation, the MEMS device 300 may be used to form a TRP pixel of a SLM of a display system. Example pixel sizes that may benefit from the MEMS device 300 and related filled vias include 6 μm pixels, 5.5 μm pixels, 5.0 μm pixels, 4.5 μm pixels, 4.0 μm pixels, 3.6 μm pixels, 2.7 μm pixels, or smaller pixels. For the example pixel sizes, pixel pitch (side-to-side size) is used, and square pixels are assumed.

In FIG. 4, the MEMS device 400 is an example of a dual spring tip pixel. In the example of FIG. 4, the MEMS device 400 includes a base 401, a first address electrode 402A, a second address electrode 402B, a bias electrode 404, spring tip vias 414A, 414B, 414C, and 414D, first electrode vias 410A, second electrode vias 410B, hinge vias 406, a torsion hinge 408, spring tips 416A to 416D, a first raised electrode 412A, a second raised electrode 412B, a mirror via 418, and a mirror 420. In the example of FIG. 4, the spring tips 416A to 416D are rounded. The base 401 is an example of the base 104 in FIG. 1. The first address electrode 402A, the second address electrode 402B, and the bias electrode 404 are example components of the electrode layer 106 in FIG. 1. The spring tip vias 414A, 414B, 414C, and 414D, the first electrode vias 410A, the second electrode vias 410B, and the hinge vias 406 are examples of the filled via(s) 112 in FIG. 1. The torsion hinge 408, the spring tips 416A to 416D, the first raised electrode 412A, and the second raised electrode 412B are example components of the mechanical layer 108 in FIG. 1. The mirror via 418 is an example of the filled via(s) 114 in FIG. 1. The mirror 420 is an example component of the moveable element(s) layer 110 in FIG. 1.

In the example of FIG. 4, various filled vias are represented including spring tip vias 414A, 414B, 414C, and 414D, first electrode vias 410A, second electrode vias 410B, hinge vias 406, and a mirror via 418. With the filled vias of FIG. 4, target characteristics for planarization (flatness) of the filled via, rigidity, or mechanical strength may be achieved. In different examples, some of the spring tip vias 414A to 414D, first electrode vias 410A, second electrode vias 410B, hinge vias 406, and the mirror via 418 may be unfilled vias while others are filled vias.

Table 3 shows different combinations of filled vias types that are possible for the example of FIG. 4. In Table 3, L refers to filled hinge vias (e.g., the hinge vias 406 are filled), M refers to filled first electrode vias (e.g., the first electrode vias 410A are filled), N refers to filled second electrode vias (e.g., the second electrode via 410B are filled), O refers to filled spring tip vias (e.g., the spring tip vias 414A, 414B, 414C, and 414D are filled), and P refers to a filled mirror via (e.g., the mirror via 418 is filled).

TABLE 3

| 1 via type | 2 via types | 3 via types | 4 via types | 5 via types |
|---|---|---|---|---|
| filled | filled | filled | filled | filled |
| L | LM | LMN | LMNO | LMNOP |
| M | LN | LMO | LMOP | |
| N | LO | LMP | LMNP | |
| O | LP | LNO | LNOP | |
| P | MN | LNP | MNOP | |
| | MO | LOP | | |
| | MP | MNO | | |
| | NO | MNP | | |
| | NP | MOP | | |
| | OP | NOP | | |

As represented in Table 3, there are up to 31 ways to combine the 5 types of filled vias represented by the letters L, M, N, O, and P. In different examples, each of the combinations represented in Table 3 may be used for a MEMS device such as the MEMS device 400 of FIG. 4. In some examples, filled hinge vias (e.g., the hinge vias 406 are filled) provide the advantages of improved hinge width uniformity and/or flatter mirrors. Other types of filled vias, including a filled first electrode vias (e.g., the first electrode vias 410A are filled), filled second electrode vias (e.g., the second electrode vias 410B are filled), filled spring tip via (e.g., the spring tip via 414A, 414B, 414C, and 414D are filled), and a filled mirror via (e.g., the mirror via 418 is filled), may provide improved reliability over time in ambient settings that vary with regard to temperature range, ultraviolet light exposure, or other ambient settings that may otherwise reduce reliability.

As shown, the position of the mirror 420 is tilted towards the spring tips 416A and 416B, which may be an on position for the mirror 420. In an example SLM, the position of the mirror 420 switches between different tilted positions (e.g., an on position in which the mirror 420 contacts spring tips 416A and 416B, and an off position in which the mirror 420 contacts the spring tips 416C and 416C) responsive to: received data; control voltages applied to the first address electrode 402A, the second address electrode 402B, and the bias electrode 404 responsive to received data; and movement of the torsion hinge 408 and mirror 420 responsive to application of the control voltages.

In the example of FIG. 4, the mirror 420 is in a first position, in which the mirror 420 contacts the spring tips 416A and 416B at contact points 422 responsive to control voltages applied to the first address electrode 402A, the second address electrode 402B, and the bias electrode 404. To change the position of the mirror 420 to another position (e.g., the mirror 420 may contact the spring tips 416C and 416D), updated control voltages are applied to the first address electrode 402A, the second address electrode 402B, and/or the bias electrode 404.

In different examples, the number of total vias and the number of filled vias between mechanical layer components and electrode layer components may vary. Similarly, in different examples, the number of total vias and the number of filled vias between mechanical layer components and mirror layer components may vary. The dimensions of each filled via may vary and may be selected to facilitate layout, spacing, and/or miniaturization of a particular MEMS device or related product. Without limitation, the MEMS device 400 may be used to form a dual spring tip pixel of a SLM of a display system. Example pixel sizes that may benefit from the MEMS device 400 and related filled vias may range from 16 μm pixels down to 2.7 μm pixels or smaller.

In FIG. 5, the MEMS device 500 is an example of a phase light modulator (PLM) or related pixel. The MEMS device 500 includes a base 502, bottom electrode 504, support vias 506A, 506B, 506C, and 506D (sometimes referred to collectively as support vias 506 herein), hinges 508A, 508B, 508C, and 508D (sometimes referred to collectively as hinges 508 herein), mirror plate 510, top plate 512, and mirror vias 514A, 514B, 514C, 514D, and 514E (sometimes referred to collectively as mirror vias 514 herein). The base 502 is an example of the base 104 in FIG. 1. The bottom electrode 504 is an example component of the electrode layer 106 in FIG. 1. The support vias 506 are examples of the filled via(s) 112 in FIG. 1. The hinges 508A, 508B, 508C, and 508D (sometimes referred to collectively as hinges 508 herein) and top plate 512 are example components of the mechanical layer 108 in FIG. 1. The mirror vias 514 are examples of the filled via(s) 114 in FIG. 1. The mirror plate 510 is an example component of the moveable element(s) layer 110 in FIG. 1.

In some examples, the support vias 506, the hinges 508, the mirror plate 510, the top plate 512, and the mirror vias 514 may be aluminum alloys in one example. In the example of FIG. 5, the base 502 is split to represent its thickness may vary. In some examples, the base 502 includes a CMOS memory array, such as an SRAM memory array. Bottom electrode 504 is also referred to as an electrode structure. In some examples, the bottom electrode 504 includes four segments (e.g., four electrodes) and a bias electrode. The four electrodes may be individually addressed to provide sixteen discrete positions for mirror plate 510. Support vias 506 couple the bias electrode portion of bottom electrode 504 to hinges 508. Each of the hinges 508 is coupled to an outside edge of a support via 506, away from the center of top plate 512. If hinges 508 were coupled to the center of a support via 506, top plate 512 would be smaller. In the example of FIG. 5, top plate 512 is larger. A larger top plate allows for more electrostatic force to be created between bottom electrode 504 and top plate 512. The hinges 508 are also coupled to top plate 512. In addition, each hinge 508 has a 90 degree turn 516A, 516B, 516C, and 516D, (sometimes referred to collectively as turns 516 herein) where the hinge couples to top plate 512. The turns 516 provide flexibility for a hinge 508, so the hinge 508 may flex if a voltage difference exists between top plate 512 and bottom electrode 504, which allows top plate 512 to move up and down relative to bottom electrode 504. Mirror plate 510 is coupled to top plate 512 by way of mirror vias 514 (shown as dashed lines in FIG. 1A).

In operation, a bias voltage is applied to support vias 506, hinges 508, top plate 512, and mirror plate 510, which are coupled to one another and therefore are each at the same bias voltage. The bias voltage may be 0 V in one example, or could be another voltage in another example. Voltages greater than 0 V are applied to some combination of the four segments of bottom electrode 504. The voltage difference between the bottom electrode 504 and the top plate 512 creates an electrostatic force that pulls the top plate 512 down toward bottom electrode 504. Mirror plate 510 moves down with top plate 512 as well. The movement up and down of top plate 512 and mirror plate 510 (with respect to bottom electrode 504) modulates the phase of the light that is reflected by mirror plate 510. Voltages are applied to different combinations of the segments of bottom electrode 504 to move mirror plate 510 and top plate 512 to different vertical positions. Moving the mirror plate 510 up and down at a high frequency modulates the phase of the reflected light, and images are produced using an array of mirror plates 510.

In some examples, the MEMS device 500 has a 4-bit electrode design for bottom electrode 504, which provides up to sixteen discrete vertical positions for mirror plate 510. With the MEMS device 500, each hinge 508 connects tangentially to an edge, instead of a center, of a support via 506. By connecting to an edge of a support via 506, top plate 512 is larger, and more usable area beneath top plate 512 is available for bottom electrode 504. A larger bottom electrode 504 allows for more electrostatic force to be created between bottom electrode 504 and top plate 512, which is useful for increasing the amount of vertical movement of top plate 512 and mirror plate 510.

In FIG. 5, the support vias 506 and the mirror vias 514 are examples of filled vias. With the filled vias of FIG. 5, target characteristics for planarization (flatness) of the filled via, rigidity, or mechanical strength may be achieved. In different examples, some of the support vias 506 and the mirror vias 514 may be unfilled vias while others are filled vias. In some examples, filled supports posts (e.g., the support vias 506 are filled) provide the advantages of improved hinge width uniformity and/or flatter mirrors and may be prioritized over other filled via options. Other types of filled vias, including filled mirror via posts (e.g., the mirror vias 514 are filled), may provide improved reliability over time in ambient settings that vary with regard to temperature range, ultraviolet light exposure, or other ambient settings that may otherwise reduce reliability.

In different examples of the MEMS device 500, the number of total vias and the number of filled vias between mechanical layer components and electrode layer components may vary. Similarly, in different examples, the number of total vias and the number of filled vias between mechanical layer components and mirror layer components of the MEMS device 500 may vary. The dimensions of each filled via may vary and may be selected to facilitate layout, spacing, and/or miniaturization of a particular MEMS device or related product. Without limitation, the MEMS device 500 may be used to form a pixel of a PLM of a display system. Example pixel sizes that may benefit from the MEMS device 500 and related filled vias may range from 16 μm pixels down to 2.7 μm pixels or smaller.

In FIG. 6, the MEMS device 600 is an example of another PLM or related pixel. In some examples, the MEMS device 600 has a 4-bit electrode design. The MEMS device 600 includes a base 602, bottom electrode 604, support vias 606A, 606B, 606C, and 606D (sometimes referred to collectively as support vias 606 herein), hinges 608A, 608B, 608C, and 608D (sometimes referred to collectively as hinges 608 herein), mirror plate 610, top plate 612, and mirror vias 614A, 614B, 614C, 614D, and 614E (sometimes referred to collectively as mirror vias 614 herein). The base 602 is an example of the base 104 in FIG. 1. The bottom electrode 604 is an example component of the electrode layer 106 in FIG. 1. The support vias 606 are examples of the filled via(s) 112 in FIG. 1. The hinges 608A, 608B, 608C, and 608D (sometimes referred to collectively as hinges 608 herein) and top plate 612 are example components of the mechanical layer 108 in FIG. 1. The mirror vias 614 are examples of the filled via(s) 114 in FIG. 1. The mirror plate 610 is an example component of the moveable element(s) layer 110 in FIG. 1

In some examples, the support vias 606, the hinges 608, the mirror plate 610, the top plate 612, and the mirror vias 614 may be aluminum alloys in one example. In the example of FIG. 6, the base 602 is split to represent its thickness may vary. In some examples, the base 602 includes a CMOS SRAM memory array. Bottom electrode 604 is also referred to as an electrode structure. In some examples, the bottom electrode 604 includes four segments that are individually addressed to provide up to sixteen discrete positions for mirror plate 610. Bottom electrode 604 may also include a bias electrode. Support vias 606 couple the bias electrode portion of bottom electrode 604 to hinges 608. Each of the hinges 608 is coupled to an outside edge of a support via 606, away from the center of top plate 612 (instead of being coupled to the center of a support via 606). The hinges 608 are also coupled to top plate 612. In addition, each of the hinges 608 has two 90 degree turns: one turn at a corner of the MEMS device 600 (turns 616A, 616B, 616C, and 616D, collectively turns 616) and one turn where the hinge couples to top plate 612 (turns 618A, 618B, 618C, and 618D, collectively turns 618). The turns 616 and 618 provide flexibility for a hinge 608, so the hinge 608 may flex if a voltage difference exists between top plate 612 and bottom electrode 604, which allows top plate 612 to move up and down relative to bottom electrode 604. Two turns in each hinge 608 may provide more relief of hinge stresses than one turn in each hinge 608. Mirror plate 610 is coupled to top plate 612 by way of mirror vias 614 (shown as dashed lines in FIG. 6).

The MEMS device 600 of FIG. 6 operates similarly to the MEMS device 500 of FIG. 5. In short, the voltage differential between the bottom electrode 604 and the top plate 612 creates an electrostatic force that pulls the top plate 612 down toward bottom electrode 604. Mirror plate 610 moves down with top plate 612 as well. The movement up and down of mirror plate 610 modulates the phase of the light that is reflected by mirror plate 610 to produce images.

In some examples, the bottom electrode 604 of the MEMS device 600 has a 4-bit electrode design to provide up to sixteen discrete vertical positions for mirror plate 610. In different examples, the MEMS device 600 may use 2, 4, 5, or more bits. While use of more bits is desirable, memory cell size and cost considerations may limit the number of bits used in a particular application.

With the MEMS device 600, each hinge 608 couples to top plate 612 on an adjacent side from a support via 606 that each respective hinge couples to. For example, hinge 608A couples to support via 606A. Hinge 608A couples to top plate 612 on a side of top plate 612 that is adjacent to the side of top plate 612 where support via 606A is located. The hinge design shown for the MEMS device 600 may provide increased hinge compliance and additional relief of hinge stresses for better thermal stability compared to the MEMS device 500. Also, the MEMS device 600 allows alternate locations for support vias 606 compared to the MEMS device 500.

In FIG. 6, the support vias 606 and the mirror vias 614 are examples of filled vias. With the filled vias of FIG. 6, target characteristics for planarization (flatness) of the filled via, rigidity, or mechanical strength may be achieved. In different examples, some of the support vias 606 and the mirror vias 614 may be unfilled vias while others are filled vias. In some examples, filled supports posts (e.g., the support vias 606 are filled) provide the advantages of improved hinge width uniformity and/or flatter mirrors and may be prioritized over other filled via options. Other types of filled vias, including filled mirror via posts (e.g., the mirror vias 614 are filled), may provide improved reliability over time in ambient settings that vary with regard to temperature range, ultraviolet light exposure, or other ambient settings that may otherwise reduce reliability.

In different examples, the number of total vias and the number of filled vias between mechanical layer components and electrode layer components of the MEMS device 600 may vary. Similarly, in different examples, the number of total vias and the number of filled vias between mechanical layer components and mirror layer components of the MEMS device 600 may vary. The dimensions of each filled via may vary and may be selected to facilitate layout, spacing, and/or miniaturization of a particular MEMS device or related product. Without limitation, the MEMS device 600 may be used to form a pixel of a PLM of a display system. Example pixel sizes that may benefit from the MEMS device 600 and related filled vias may range from 16 μm pixels down to 2.7 μm pixels or smaller.

In some examples, the fabrication of a MEMS device begins with a completed memory circuit. The memory circuitry may be, for example, a complementary metal-oxide semiconductor (CMOS) memory circuit. Through the use of photomask layers, the MEMS device superstructure is formed with alternating layers of aluminum or other metal for electrode layer components, mechanical layer components, and mirror layer components. In different examples, the aluminum or other metal may be sputter-deposited and plasma-etched. A hardened carbon polymer is used for sacrificial layers to form air gaps of a MEMS device. The sacrificial layers may be plasma-etched.

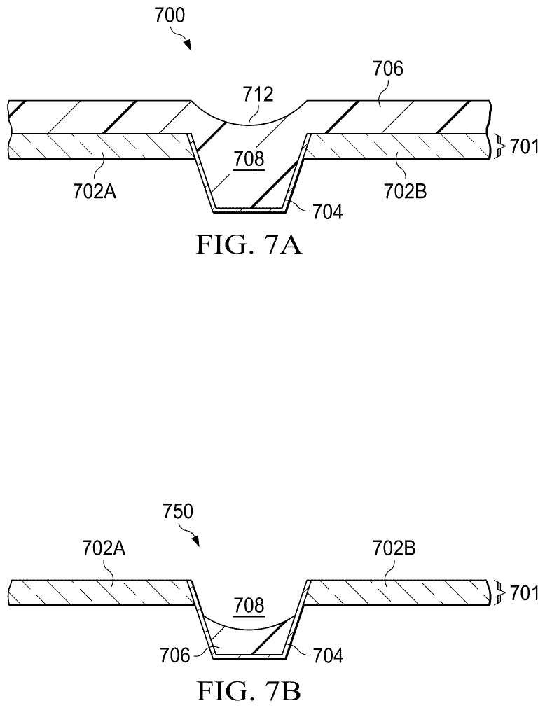

FIGS. 7A and 7B are cross-sectional views 700 and 750 showing filler application and etching results in accordance with various examples. The filler application and etching results represented in FIGS. 7A and 7B provide an overview of filled via fabrication that is applicable to: any of the filled via(s) 112 in FIG. 1; any of the filled via(s) 114 in FIG. 1; any of the hinge vias 206, the first electrode vias 210A, the second electrode vias 210B, the first spring tip via 214A, the second spring tip via 214B, and/or the mirror via 218 of FIGS. 2A to 2E; any of the spring tip vias 314A to 314C, the first electrode via 310A, the second electrode via 310B, the hinge vias 306, and/or the mirror via 318 of FIG. 3; any of the spring tip vias 414A, 414B, 414C, and 414D, the first electrode vias 410A, the second electrode vias 410B, the hinge vias 406, and/or the mirror via 418 of FIG. 4; any of the support vias 506 and/or the mirror vias 514 in FIG. 5; and any of the support vias 606 and/or the mirror vias 614 in FIG. 6.

In the cross-sectional view 700 of FIG. 7A, a metal layer 701 with portions 702A and 702B is represented. The space between the portions 702A and 702B of the metal layer 701 is a via hole 708. A metal liner 704 is formed between the portions 702A and 702B of the metal layer 701 in the shape of the via hole 708. In the example of FIG. 7A, a filler 706 (sometimes referred to as a “planarization layer” herein) fills the via hole 708 and covers the portions 702A and 702B of the metal layer 701. In some examples, the filler 706 (e.g., oxide) is applied using a spin-on application. As shown, the filler 706 may have a divot 712. In the example of FIG. 7A, the filler 706 fills all of the via hole 708. As shown, a divot 712 may remain. With the spin-on application, the size of the divot 712 in the filler 706 is reduced compared to other deposition techniques.

In the cross-sectional view 750 of FIG. 7B, the filler 706 has been removed from covering the portions 702A and 702B of the metal layer 701 using an etching technique. As shown, some of the filler 706 remains in the via hole 708. In different examples, the amount of filler 706 remaining in the via hole 708 may vary.

With the filler 706 applied as in FIG. 7A, the metal layer 701 of FIG. 7B may have a more uniform planarization after the etching result of FIG. 7B. Accordingly, subsequent layers applied on top of the metal layer 701 have improved planarization.

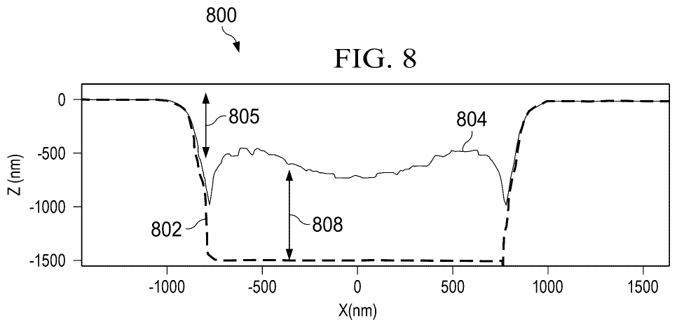

FIG. 8 is a graph 800 showing a cross section of a via and the filler dimensions in accordance with various examples. In the example of FIG. 8, the shape of the via 802 represented by the dashed line has a width of approximately 1500 nm and a depth of approximately 1500 nm. The shape of the filler 804 is non-linear due to the effect of etching, resulting in a varied etching depth 805. In the example of FIG. 8, the etching depth 805 is approximately 500 nm and the filler depth 808 is approximately 1000 nm with some variance. For example, the etching depth 805 may increase near the edges and middle of the filler 804 in the via 802.

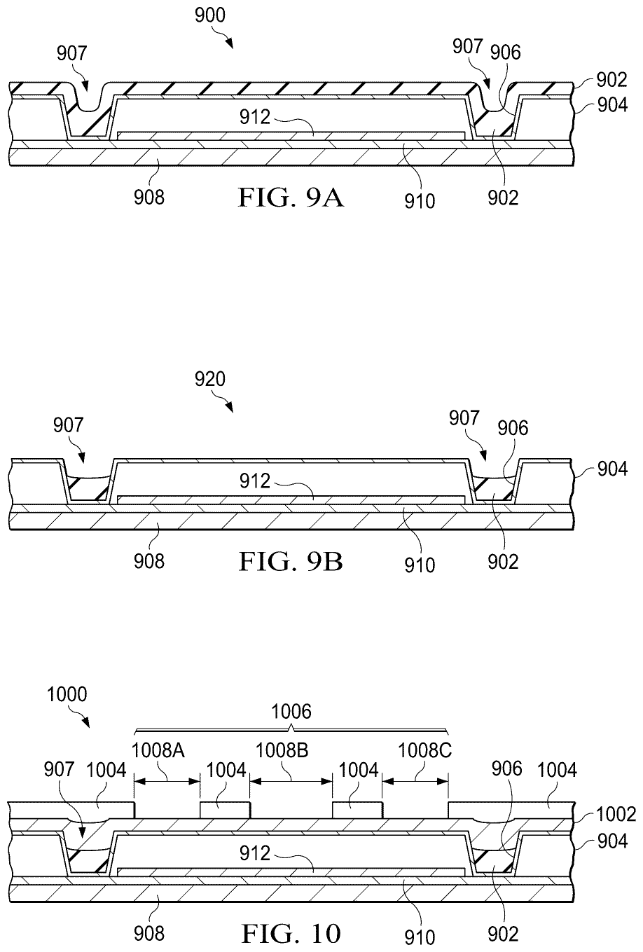

FIGS. 9A and 9B are cross-sectional views 900 and 920 showing some MEMS device layers during fabrication in accordance with various examples. The fabrication results represented in FIGS. 9A and 9B provide an overview of filled via fabrication that is applicable to: hinge vias of the filled via(s) 112 in FIG. 1; the hinge vias 206 of FIGS. 2A to 2E; the hinge vias 306 of FIG. 3; the hinge vias 406 of FIG. 4; the support vias 506 in FIG. 5; and the support vias 606 in FIG. 6.

In the cross-sectional view 900, MEMS device layers include a filler (e.g., an oxide planarization layer) 902, a spacer resist layer 904, a hinge metal layer 906 between the filler 902 and the resist layer 904. The MEMS device layers also include a first metal layer 908, a second metal layer 910, and a third metal layer or antireflective coating (ARC) 912. In the example of FIG. 9A, third metal layer or ARC 912 is removed from the vias 907 so that hinge metal layer 906 in the vias 907 contacts the second metal layer 910.

In the cross-sectional view 920 of FIG. 9B, the filler 902 has been etched such that the hinge metal layer 906 is exposed. As shown, some of the filler 902 remains in the vias 907. In some examples, the first metal layer 908, the second metal layer 910, and the third metal layer or ARC 912 are made from different metals (e.g., TiOx on TIN on aluminum on TIN on Ti). In some examples, the first metal layer 908 includes Ti, TiN, and AlTiSi sub-layers, the second metal layer 910 includes TiN and TiO2 sub-layers, and the third metal layer is SiO2.

In some examples, the filler 902 is applied using a spin-on application. With the spin-on application, the filler 902 improves the uniformity of the hinge metal layer 906 and reduces the size of divots in subsequent layers added on top of the hinge metal layer 906 compared to other deposition techniques. Accordingly, subsequent layers (e.g., more vias and a mirror) applied on top of the hinge metal layer 906 have improved planarization.

FIG. 10 is a cross-sectional view 1000 showing subsequent fabrication results for a MEMS device relative to FIGS. 9A and 9B in accordance with various examples. In the cross-sectional view 1000, the same layers described in FIG. 9B are represented. In the example of FIG. 10, an anti-reflective coating 1002 (e.g., SiO2) and a hinge pattern resist layer 1004 cover the hinge metal layer 906 and the filler 902.

The hinge pattern resist layer 1004 includes a pattern 1006 including gaps 1008A, 1008B, and 1008C. The gaps 1008A, 1008B, and 1008C are where hinge metal is removed to create a final hinge metal layout. To complete the hinge, the anti-reflective coating 1002 and hinge metal layer 906 are subsequently etched based on the pattern 1006. In the example of FIG. 10, the pattern 1006 defines a hinge pattern.

With the filler 902 in the vias 907, a target planarization for the bottom anti-reflective coating 1002 and the hinge pattern resist layer 1004 is achieved, which improves the accuracy of the dimensions for the gaps 1008A, 1008B, and 1008C. With accurate placement of the gaps 1008A, 1008B, and 1008C, a more accurate hinge structure is possible. Because the thickness, the width, and the length of a hinge determines the mechanical properties of MEMS device movement and affects operating voltages, improving the accuracy of via gaps and related hinges is key MEMS device design consideration. As miniaturization of MEMS devices increases, the importance of accurate dimensions for the gaps 1008A, 1008B, and 1008C increases.

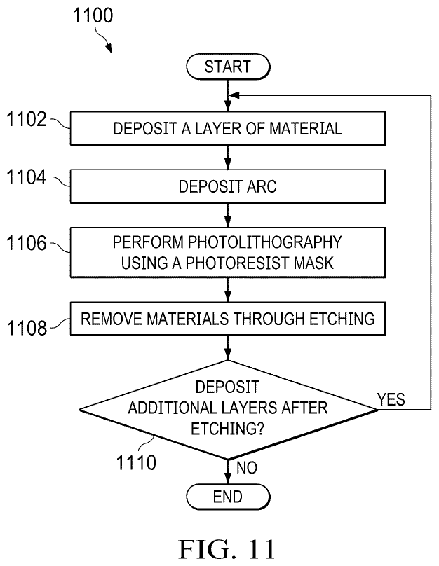

FIG. 11 is a flowchart representative of a method 1100 to fabricate a MEMS device as described in accordance with the teachings of this disclosure. In some examples, the method 1100 may be applied iteratively to fabricate electrode layer components, mechanical layer components, unfilled vias, filled vias, and/or a mirror. In some examples, the method 1100 is performed iteratively as needed to form components of the electrode layer 106, filled via(s) 112, components of the mechanical layer 108, filled via(s) 114, and/or components of the moving element(s) layer 110 in FIG. 1. In some examples, the method 1100 is performed iteratively as needed to form components of the electrode layer 222, the hinge vias 206, the first electrode vias 210A, the second electrode vias 210B, the first spring tip via 214A, the second spring tip via 214B, components of the mechanical layer 224, the mirror via 218, and/or the mirror 220 of FIGS. 2A to 2E. In some examples, the method 1100 is performed iteratively as needed to form the first address electrode 302A, the second address electrode 302B, the bias electrode 304, the spring tip vias 314A to 314C, the first electrode via 310A, the second electrode via 310B, the hinge vias 306, the cantilever hinge 308, the spring tips 316A to 316C, the first raised electrode 312A, the second raised electrode 312B, the mirror via 318, and/or the mirror 320 in FIG. 3. In some examples, the method 1100 is performed iteratively as needed to form the first address electrode 402A, the second address electrode 402B, the bias electrode 404, the spring tip vias 414A, 414B, 414C, and 414D, the first electrode vias 410A, the second electrode vias 410B, the hinge vias 406, the torsion hinge 408, the spring tips 416A to 416D, the first raised electrode 412A, the second raised electrode 412B, the mirror via 418, and/or the mirror 420 of FIG. 4.

In some examples, the method 1100 is performed iteratively as needed to form the bottom electrode 504, the support vias 506, the hinges 508, the mirror plate 510, the top plate 512, and/or mirror vias 514 in FIG. 5. In some examples, the method 1100 is performed iteratively as needed to form the bottom electrode 604, the support vias 606, the hinges 608, the mirror plate 610, the top plate 612, and/or the mirror vias 614 of FIG. 6.

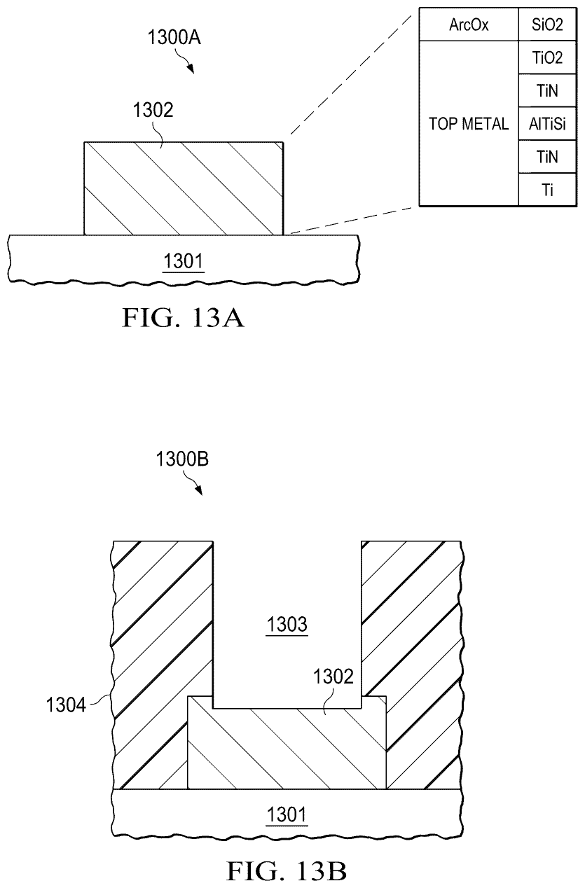

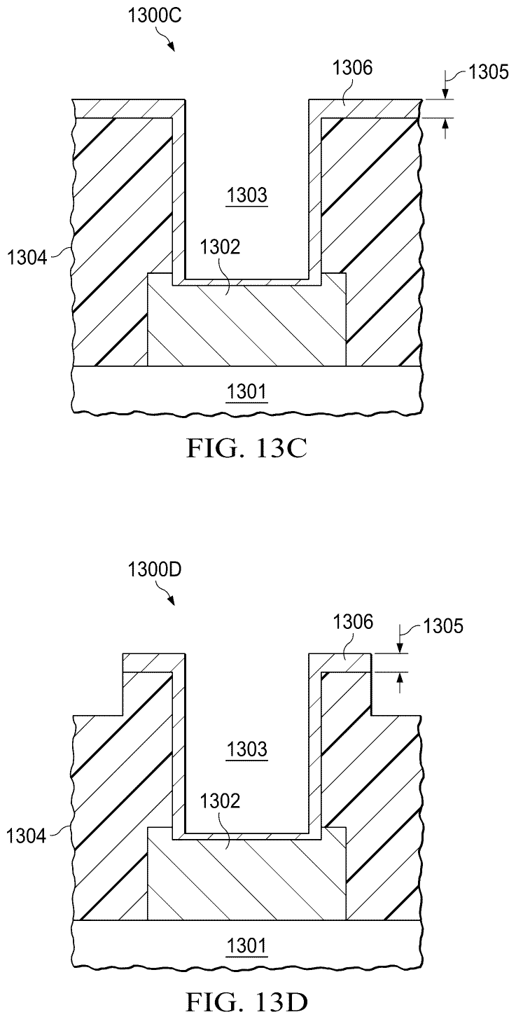

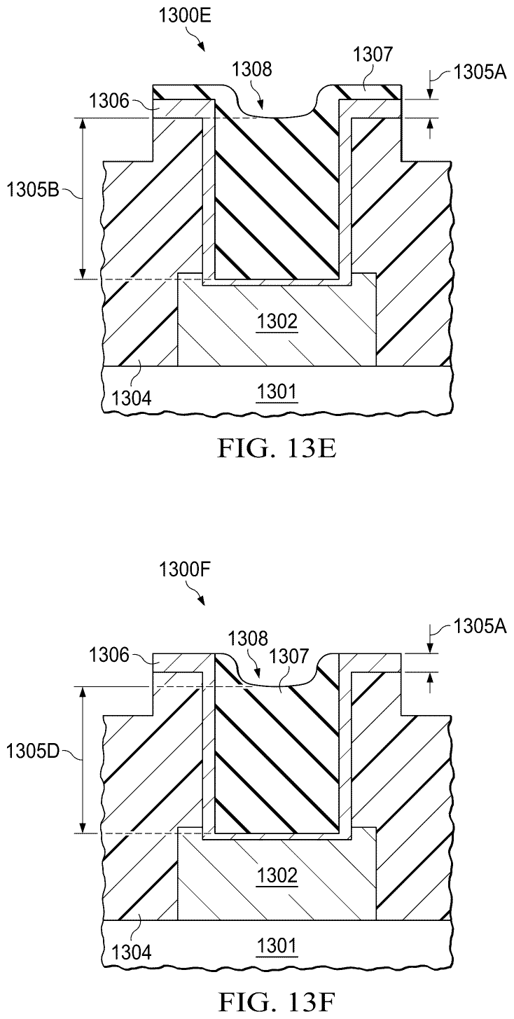

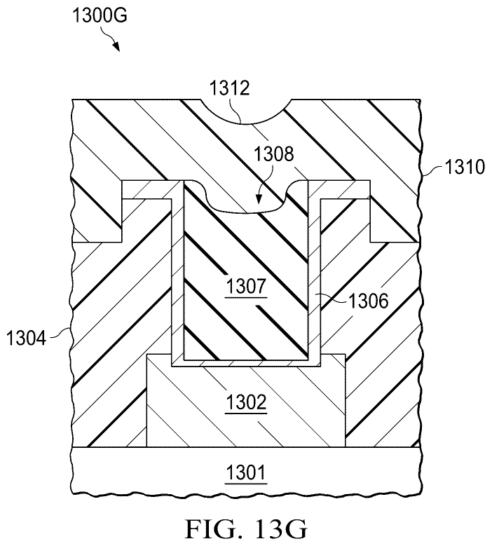

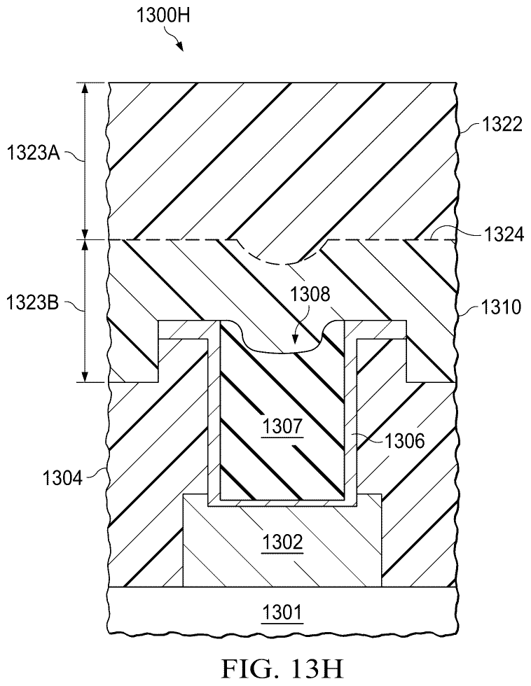

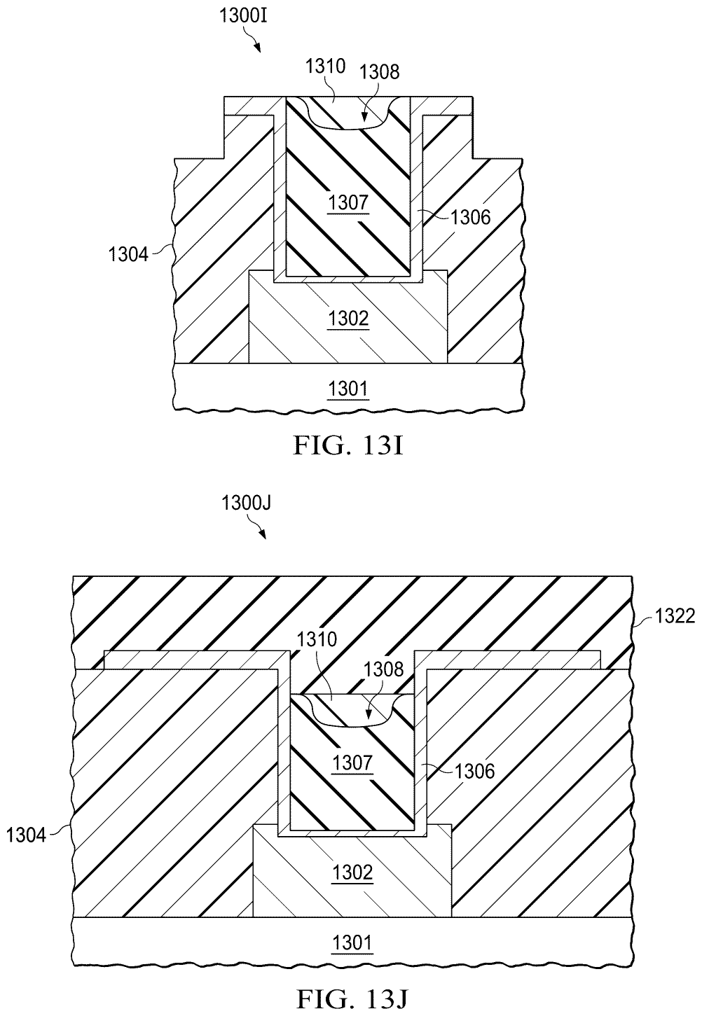

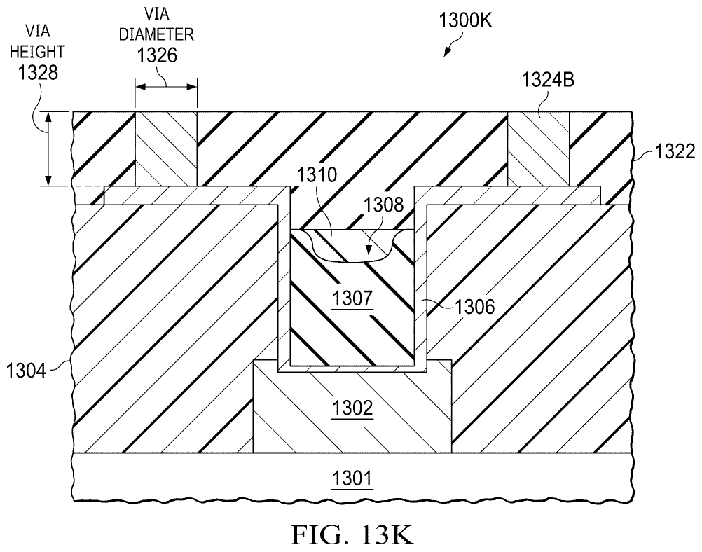

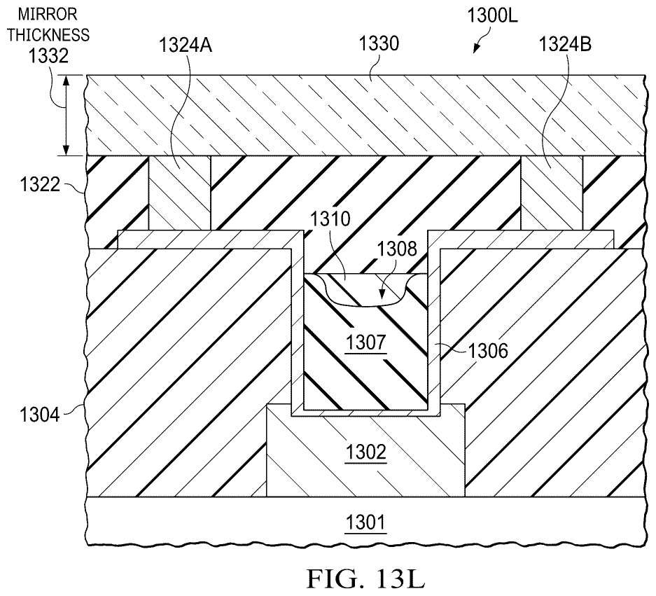

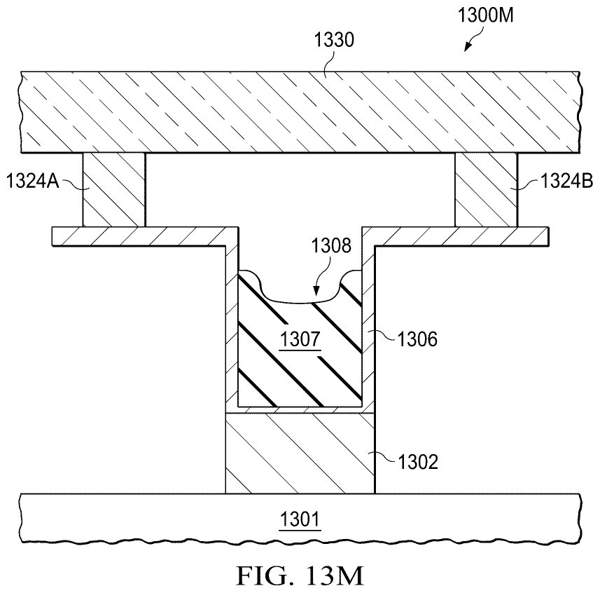

The example method 1100 begins by depositing a layer of material at block 1102. During an iteration of the method 1100, block 1102 is used to deposit material for metal layers. The second metal layer 910 in FIGS. 9A 9B, and 10, the third metal layer or ARC 912 in FIGS. 9A and 9B, and 10, or the metal stack 1302 in FIGS. 13A to 13M are examples of metal layers deposited at block 1102. The material for metal layers may be deposed, for example, over a base (e.g., the base 104 in FIGS. 1A and 1B, the base 201 in FIGS. 2A to 2E, the base 301 in FIG. 3, the base 401 in FIG. 4, the base 502 in FIG. 5, or the base 602 in FIG. 6).

In some examples, during a subsequent iteration of the method 1100, block 1102 is used to deposit material for electrode layer components, such as those described in FIGS. 1A, 1B, 2A-2E, 3, 4, 5, and 6. The material for electrode layer components may be deposited, for example, over the metal layers previously deposited and patterned in a previous iteration or iterations of the method 1100.

In some examples, during a subsequent iteration of the method 1100, block 1102 is used to deposit material for filled vias (e.g., filled hinge vias, filled electrode vias, filled spring tip vias, etc.) and/or unfilled vias, such as those described in FIGS. 1, 2A-2E, 3, 4, 5, and 6. The material for filled vias and/or unfilled vias may be deposited, for example, over the electrode layer components previously deposited and patterned in a previous iteration or iterations of the method 1100.

In some examples, during a subsequent iteration of the method 1100, block 1102 is used to deposit material for mechanical layer components, such as those described in FIGS. 1, 2A-2E, 3, 4, 5, and 6. The material for mechanical layer components may be deposited, for example, over the filled vias and/or unfilled vias previously deposited and patterned in a previous iteration or iterations of the method 1100.

In some examples, during a subsequent iteration of the method 1100, block 1102 is used to deposit material for a filled mirror via or unfilled mirror via, such as those described in FIGS. 1, 2A-2E, 3, 4, 5, and 6. The material for filled mirror via or unfilled mirror via may be deposited, for example, over mechanical layer components previously deposited and patterned in a previous iteration or iterations of the method 1100.

In some examples, during a subsequent iteration of the method 1100, block 1102 is used to deposit material for a mirror, such as those described in FIGS. 1, 2A-2E, 3, 4, 5, and 6. The material for mirror via may be deposited, for example, over a filled mirror via or unfilled mirror via previously deposited and patterned in a previous iteration or iterations of the method 1100.

In some examples, an initial iteration of the method 1100 deposits material on the surface of a wafer or substrate (e.g., silicon) at block 1102. Depending on the iteration of the method 1100 and the particular MEMS device being fabricated, the material deposited at block 1102 may be made from any suitable material (e.g., metals, organic materials, etc.). Block 1102 may be performed using any IC deposition technique, including but not limited to chemical vapor deposition, atomic layer deposition, physical vapor deposition, molecular-beam epitaxy, etc. At block 1104, an anti-reflective coating (ARC) may optionally be deposited. If implemented, block 1104 occurs after material deposited at block 1102 is exposed to oxygen plasma but before patterning. Depositing ARC is used to avoid reflections from occurring under the photoresist and improves the photoresist's performance at smaller semiconductor nodes.

At block 1106, photolithography is performed using a photoresist mask. With block 1106, specific portions of the wafer are exposed. The patterning of block 1106 may be performed using any IC deposition technique, including but not limited to optical lithography, electron beam lithography, soft lithography, x-ray lithography, etc.

At block 1108, materials are removed through etching. In some examples, block 1108 uses a plasma etcher tool to etch previously deposited material to remove portions of the material based on the photoresist. Block 1108 may be performed using any suitable etching technique, including but not limited to wet etching, isotropic radical etching, reactive ion etching, physical sputtering and ion milling, etc. The final iteration of block 1108 may be referred to as a release stage, during which sacrificial layers are removed and the MEMS device becomes a stand-alone structure.

The example method 1100 includes determining whether to deposit additional layers after patterning at block 1110. If additional layers are to be deposited (block 1110: Yes), the method 1100 returns to block 1102. If no additional layers remain to be deposited (block 1110: No), the MEMS fabrication is complete and the example method 1100 ends.

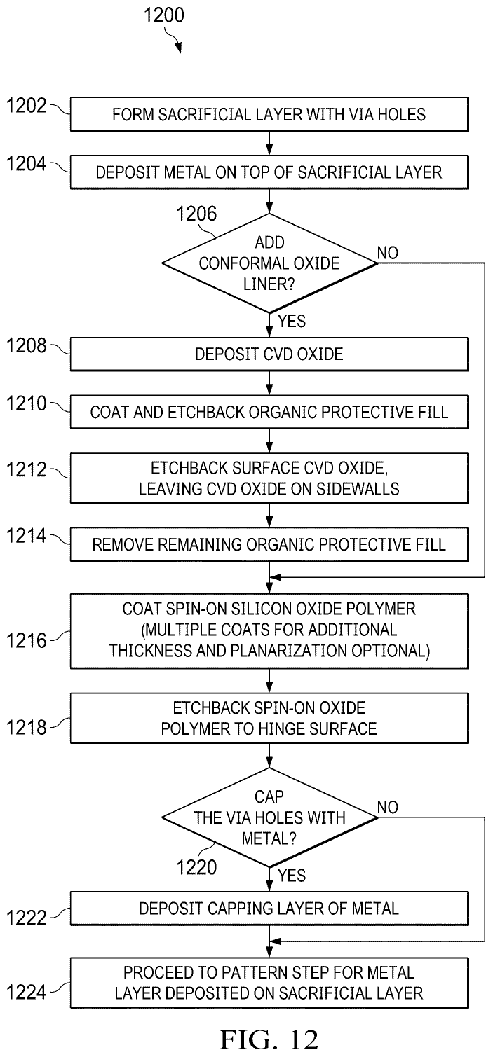

FIG. 12 is a flowchart showing a MEMS device hinge fabrication method 1200 in accordance with various examples. The MEMS device hinge fabrication method 1200 may be used to fabricate a MEMS device hinge (e.g., a hinge of the mechanical layer 108 in FIGS. 1A and 1B, the torsion hinge 208 in FIG. 2, the cantilever hinge 308 in FIG. 3, the torsion hinge 408 in FIG. 4, the hinges 508 in FIG. 5, or the hinges 608 in FIG. 6). In some examples, iterations of the method 1100 may be performed before the MEMS device hinge fabrication method 1200 to add material and pattern surfaces of a MEMS device that are under the hinge (e.g., electrode layer components). After the MEMS device hinge fabrication method 1200 is completed, multiple iterations of the method 1100 may be performed to add material and pattern surfaces of a MEMS device around or above the hinge (e.g., other mechanical layer components, a mirror via, and a mirror) until a MEMS device (e.g., the MEMS device 100 in FIGS. 1A and 1B, the MEMS device 200 in FIGS. 2A to 2E, the MEMS device 300 in FIG. 3, the MEMS device 400 in FIG. 4, the MEMS device 500 in FIG. 5, or the MEMS device 600 in FIG. 6) is completed. FIGS. 13A to 13M are cross-sectional views 1300A to 1300M of MEMS device fabrication steps in accordance with various examples and which represent at least some of the steps or results of the MEMS device fabrication methods 1100 and 1200. In FIGS. 13A to 13M, the layers are not to scale.

For the method 1200, a stack of metals (e.g., TiOx on TIN on aluminum on TIN on Ti) is assumed to have already been deposited on a CMOS substrate wafer. The cross-sectional view 1300A of FIG. 13A shows an example metal stack 1302 on a substrate 1301. In the example of FIG. 13A, the metal stack 1302 includes (from bottom to top) a Ti sub-layer, a first TiN sub-layer, an AlTiSi sub-layer, a second TiN sub-layer, a TiO2 sub-layer, and a SiO2 sub-layer, where the thickness of the sub-layers may vary. In some examples, the first TI sub-layer has a thickness of 200 Angstroms, the first TiN sub-layer has a thickness of 425 Angstroms, the AlTiSi sub-layer has a thickness of 2500 Angstroms, the second TiN sub-layer has a thickness of 900 Angstroms, the TiO2 sub-layer has a thickness of 125 Angstroms, and the SiO2 sub-layer has a thickness of 640 Angstroms. In different examples, the thickness of the sub-layers of the metal stack 1302 may vary.

In some examples, the metal stack 1302 is patterned and etched to form a metal circuit layer. At block 1202, a sacrificial layer with via holes. The cross-sectional view 1300B of FIG. 13B shows an example sacrificial layer 1304 and via hole 1303 formed on the metal stack 1302. In some examples, the sacrificial layer 1304 is SION. In some examples, the via hole 1303 is patterned and etched through the sacrificial layer 1304 and TiOx sub-layer of the metal stack 1302 to open up the TiN sub-layer of the metal stack 1302. In some examples, the sacrificial layer 1304 is patterned using photolithographic masks and the via hole1303 is aligned with the via openings to the TIN layer of the metal stack 1302.

At block 1204, a metal is deposited on top of the sacrificial layer including the via openings formed in block 1212. The cross-sectional view 1300C of FIG. 13C shows a metal 1306 deposited on top of the sacrificial layer 1304 as in block 1204. In some examples, the metal 1306 is a Ti-AI alloy. In some examples, the deposited metal 1306 makes electrical contact with the TiN layer at the bottom of the via hole 1303 formed in block 1202. As shown in FIG. 13C, the metal 1306 covers the surface of the sacrificial layer 1304, including the sides and bottom of the via hole 1303 formed in the first sacrificial layer 1304.

If a conformal oxide liner is to be added (block 1206; Yes), the method 1200 includes depositing chemical vapor deposition (CVP) oxide at block 1208. In the example of FIG. 13C, block 1208 is performed, for example, to increase the thickness 1305 of some of the metal 1306. In some examples, block 1208 is used to increase the thickness 1305 of the metal 1306 at the top of the sacrificial layer 1304 compared to the metal 1306 on the sides and bottom of the via hole 1303. In some examples, the method 1200 may include the step (not shown in FIG. 12) of adjusting the dimensions of the metal 1306 and/or the first sacrificial layer 1304 as in the cross-sectional view 1300D of FIG. 13D.

At block 1210, coating and etchback of an organic protective filler is performed. At block 1212, etchback of surface CVD oxide is performed, leaving CVD oxide on sidewalls. At block 1214, remaining organic protective fill is removed. At block 1216, spin-on silicon oxide polymer coating is performed. The cross-sectional view 1300E in FIG. 13E shows example results of block 1216, where a filler 1307 (e.g., a silicon oxide polymer coating) covers the metal 1306 and fills the via hole 1303, resulting in a via 1308 that is filled. In some examples, multiple coats are applied at block 1216 for additional thickness and planarization. In some examples, the spin-on filler process of block 1216 involves: dispensing a spin-on filler, such as a silicon oxide with polymer; adjusting the wafer rotation speed and time to achieve a target thickness and uniformity; and performing a hot plate bake at 175° C. to 205° C. In some examples, multiple coats are used to better fill and planarize a via. In some examples, silicon oxide with polymer provides a low etch rate in oxygen plasma etch processes, which facilitates planarization efforts. Also, silicon oxide with polymer has a lower cure temperature compared to silicon oxide films deposited through other processes (e.g., chemical vapor deposition). In some examples, the operations of block 1216 avoid exposing a MEMS device to temperatures above 225° C. If a conformal oxide line is not to be added (block 1206: No), the method 1200 proceeds directly to block 1216.

At block 1218, filler not in the vias is etched. The cross-sectional view 1300F in FIG. 13F shows the results of block 1218, where the filler 1307 has been etched from the top surface of the metal 1306. As shown in FIG. 13F, the amount of filler 1307 in the via 1308 relative to the metal 1306 is adjusted at block 1218. In some examples, block 1218 includes etchback of a spin-on polymer to a hinge surface. As shown in the cross-sectional view 1300F in FIG. 13F, some filler 1307 may remain in the via 1308 after the operations of block 1218.

If the via holes are to be capped with metal (block 1220: Yes), a capping layer of metal is deposited at block 1222 and the method 1200 proceeds to block 1224. The result of block 1222 (not specifically shown) would be metal covering the filler 1307 of FIG. 13F. The method 1200 also proceeds to block 1224 if the via holes are not to be capped with metal (block 1220: No). At block 1224, the method 1200 proceeds with a pattern step for metal layer deposited on a sacrificial layer. In some examples, a Ti-AI layer may be patterned and etched to form a mechanical layer component (e.g., a torsional hinge, a cantilever hinge, a spring tip, a raised electrode, etc.) at block 1224.

In the cross-sectional view 1300F of FIG. 13F, the via 1308 has been created by depositing, patterning, and etching various layers of materials. Example layers include the metal stack 1302, the first sacrificial layer 1304, the metal 1306, the filler 1307, and the via 1308. In some examples, the thickness 1305A of the metal 1306 may be 100-1000 Angstroms, while the thickness of the filler 1307 may vary. The filler 1307 reinforces the mechanical layer metal and/or related vias and provides support for the mirror of a MEMS device.

In some examples, the metal stack 1302 may include metals, metal alloys, a substrate, or a components of an anti-reflective coating (ARC) film stack. These layers have been deposited, patterned, and etched to form the structure shown in FIG. 13F. In some examples, metal layers may include titanium oxide, titanium nitride, and/or aluminum. In some examples, the metal stack 1302 may be a complementary metal-oxide semiconductor (CMOS) substrate, which may sit on a substrate of intermetal dielectric (IMD) oxide (not shown). In some examples, the metal stack 1302 may be built on top of a multi-layer transistor layout that includes traditional semiconductor source/drains, polysilicon gates, contacts, poly-metal dielectric, and multiple levels of interconnect metal isolated with inter-metallic dielectrics (not shown in FIG. 13A). The transistor layout may provide signals for controlling the operation of the PLM. The first sacrificial layer 1304 may be any suitable sacrificial material that is removed during a later processing step to release the MEMS device. The first sacrificial layer 1304 may be patterned and/or etched to produce the shape shown in FIG. 13F. The first sacrificial layer 1304 may be a photoresist or carbon rich film. in some examples, the material for the metal 1306 may be deposited on portions of the first sacrificial layer 1304.

In the cross-sectional view 1300G of FIG. 13G, a non-photoactive organic polymer 1310 has been deposited on the structure of FIG. 13F. The non-photoactive organic polymer 1310 may be a spin-on carbon (SOC), which is a type of organic spin-coated polymer. The non-photoactive organic polymer 1310 may be a methacrylate polymer in some examples. As shown in FIG. 13G, the via 1308 may be filled with the non-photoactive organic polymer 1310. Other organic spin-coated polymers may be used in some examples.

In some examples, the non-photoactive organic polymer 1310 is deposited and spun for a certain target thickness. In some examples, the non-photoactive organic polymer 1310 is baked to cure it. In one example, the non-photoactive organic polymer 1310 may be baked at 180-220° Celsius (C.). In one example, the non-photoactive organic polymer 1310 is baked at 175-185° C. The non-photoactive organic polymer 1310 may become rigid after baking. As seen in FIG. 13G, due to the deposition and baking process, the non-photoactive organic polymer 1310 may have a divot 1312 after it has cured. In some examples, the divot 1312 may be flattened due to the amount of filler 1307 in the via 1308.

In some examples, a second layer of non-photoactive organic polymer is deposited. For example, a second sacrificial layer 1322 of the non-photoactive organic polymer may be deposited on non-photoactive organic polymer 1310 as in the cross-sectional view 1300H of FIG. 13H. In one example, the second sacrificial layer 1322 may have a thickness 1323A between 1,000 and 10,000 Angstroms. A dashed line 1324 shows an approximate boundary between the first layer of non-photoactive organic polymer 1310 and the second sacrificial layer 1322. After the first layer of non-photoactive organic polymer 1310 is baked and cross linked, the second sacrificial layer 1322 may be deposited. The second sacrificial layer 1322 fills the divot 1312 and has a flat upper surface. After the second sacrificial layer 1322 is deposited, the structure of FIG. 13H is baked and cross linked to harden the second sacrificial layer 1322. In some examples, the structure is baked at 180-220° C. In some examples, the second sacrificial layer 1322 has a thickness 1323A that is thicker than the thickness 1323B of non-photoactive organic polymer 1310. If a divot occurs at the top of second sacrificial layer 1322, it may be a small divot that does not substantially affect the flatness of the mirror.

In the cross-sectional view 1300I of FIG. 13I, the resulting structure after the second sacrificial layer 1322 and non-photoactive organic polymer 1310 have been etched is represented. In this example, the second sacrificial layer 1322 and the non-photoactive organic polymer 1310 etch at the same rate because they are the same material. Therefore, no dome structure is present after etching such as the photoresist example described above. Rather, the top surface of non-photoactive organic polymer 1310 in via 1308 is flat. Therefore, flat structures may be created on top of non-photoactive organic polymer 1310 in subsequent processing steps. In an example, a mirror for a MEMS device may be created using the structure of FIG. 13I.

In some examples, method 1200 includes additional steps such as: coating with another sacrificial layer (e.g., of photoresist polymer); patterning using photolithography masks with via holes, including via holes; covering the sacrificial and via sidewalls with an aluminum alloy such that the aluminum alloy makes electrical contact with the TIN layer at the bottom of the vias; and patterning and etching a mirror.

FIGS. 13J to 13M show cross-sectional views 1300J, 1300K, 1300L, and 1300M showing mirror fabrication steps. In FIG. 13J, the metal stack 1302, the first sacrificial layer 1304, the metal 1306, the filler 1307, the via 1308, and non-photoactive organic polymer 1310 are represented. In some examples, a non-photoactive organic polymer 1310 is deposited and processed in two layers. In FIG. 13J, the second sacrificial layer 1322 has been added to the structure of FIG. 13I. The second sacrificial layer 1322 is deposited onto the metal 1306 and the non-photoactive organic polymer 1310.

In FIG. 13K, mirror vias 1324A and 1324B have been created in the second sacrificial layer 1322. For example, the second sacrificial layer 1322 may be patterned and etched to create the mirror vias 1324A and 1324B. The mirror vias 1324A and 1324B are the structural connection from the metal 1306 to a mirror 1330 of the MEMS device as in FIG. 13L. In some examples, the material for mirror vias 1324A and 1324B may be deposited onto the metal 1306 using any suitable method. In some examples, the material for mirror vias 1324A and 1324B is an organic polymer. The mirror vias 1324A and 1324B may be between 0.3 and 6.0 micrometers deep (e.g., the via height 1328), and may also have a via diameter 1326 between 0.3 and 6.0 micrometers. In different examples, the mirror vias 1324A and 1324B may be deep filled mirror vias and may be partially or completely filled.

In FIG. 13L, a mirror 1330 is added to the structure of FIG. 13K. After the mirror vias 1324A and 1324B are created, mirror material (such as a metal) for the mirror 1330 is deposited on the second sacrificial layer 1322 and the mirror vias 1324A and 1324B. In some examples, the mirror 1330 may be a metal such as aluminum. The mirror 1330 may have a thickness 1332 between 500 and 5000 Angstroms. In the example of FIG. 13L, the mirror 1330 has a flat supper surface, in part, because the second sacrificial layer 1322 has a flat upper surface. The second sacrificial layer 1322 has a flat upper surface because there is no dome or divot (e.g., divot 1312) in the non-photoactive organic polymer 1310.

In FIG. 13M, the sacrificial planarization materials and spacer materials (e.g., the first sacrificial layer 1304, the non-photoactive organic polymer 1310, and the second sacrificial layer 1322) have been removed. Removing these materials releases the final MEMS device. Once released, the metal 1306 and the mirror 1330 may move freely during device operation (assuming the metal 1306 is part of a hinge). Sacrificial materials and spacer materials may be removed using any suitable techniques, such as ashing, dry etching, or wet etching. After removal of the sacrificial materials, the mirror may move vertically. In some examples, after removal of the sacrificial materials, a corner of a mirror may tilt away from the plane of the MEMS device.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

1. A microelectromechanical system (MEMS) device comprising:
a mechanical layer;
a second layer; and
a via coupled between the mechanical layer and the second layer, the via comprising a metal layer having a bottom and sides, and oxide on the bottom of the metal layer between the sides of the metal layer.

2. The MEMS device of claim 1, wherein the second layer is a mirror layer.

3. The MEMS device of claim 1, wherein the second layer is an electrode layer including an electrode, the via coupling the electrode and the mechanical layer.

4. The MEMS device of claim 3, wherein the electrode is a bias electrode.

5. The MEMS device of claim 4, wherein the mechanical layer includes a spring tip, the via coupling the bias electrode and the spring tip.

6. The MEMS device of claim 4, wherein the mechanical layer includes a hinge, the via coupling the bias electrode and the hinge.

7. The MEMS device of claim 3, wherein the mechanical layer includes a raised electrode, the via coupling the raised electrode and the electrode.

8. The MEMS device of claim 1, further comprising a mirror and a spring tip, wherein the via is a first via, the metal layer is a first metal layer, the MEMS device comprises a second via, the second via comprising a second metal layer having a bottom and sides, and oxide on the bottom of the second metal layer between the sides of the second metal layer, the first via is coupled to the mechanical layer and the mirror, and the second via is coupled to the mechanical layer and the spring tip.

9. The MEMS device of claim 1, wherein the MEMS device is part of a digital micromirror device.

10. The MEMS device of claim 1, wherein the MEMS device is part of a phase light modulator.

11. A method of manufacturing a microelectromechanical system (MEMS) device, the method comprising:
forming an opening in a sacrificial layer;
depositing metal in the opening to form a via;
filling the via with spin-on oxide filler; and
etching the spin-on oxide filler.

12. The method of claim 11, wherein the filling the via with spin-on oxide filler comprises:
dispensing the spin-on oxide filler; and
adjusting a wafer rotation speed and time.

13. The method of claim 12, wherein filling the via with spin-on oxide filler further comprises: repeating dispensing the spin-on oxide filler and adjusting the wafer rotation speed and time until a target thickness and uniformity of the spin-on oxide filler is achieved.

14. The method of claim 13, wherein filling the via with spin-on oxide filler further comprises performing a hot plate bake at 175° C. to 205° C.

15. The method of claim 14, wherein the spin-on oxide filler is a silicon oxide with polymer.

16. The method of claim 11, wherein etching the spin-on oxide filler produces a filled via and the method further comprises forming a hinge coupled to the filled via.

17. A microelectromechanical system (MEMS) device comprising:
a mirror layer;
an electrode layer including an electrode;
a hinge layer;
a first via coupling the hinge layer and the mirror layer; and
a second via coupling the hinge layer and the electrode, the second via comprising an oxide filler.

18. The MEMS device of claim 17, wherein the first via comprises an oxide filler.

19. The MEMS device of claim 17, wherein the hinge layer includes a spring tip, and the MEMS device further comprises a via coupling the spring tip and the electrode, the electrode being a bias electrode, and the second via comprising an oxide filler.

20. The MEMS device of claim 17, wherein the hinge layer includes a raised electrode, and the MEMS device further comprising a third via coupling the raised electrode and the electrode, the third via comprising an oxide filler.
